(19) United States
(12) Patent Application Publication
(10) Pub. No.: US 2025/0212613 A1
(43) Pub. Date: Jun. 26, 2025

(54) DISPLAY DEVICE AND METHOD FOR FABRICATION THEREOF

(71) Applicant: Samsung Display Co., LTD., Yongin-si (KR)

(72) Inventors: Yung Bin CHUNG, Yongin-si (KR); Do Keun SONG, Yongin-si (KR)

(21) Appl. No.: 18/776,135

(22) Filed: Jul. 17, 2024

(30) Foreign Application Priority Data
Dec. 21, 2023 (KR) 10-2023-0188083

(51) Int. Cl. H10K 59/122; H10K 59/12; H10K 59/80; H10K 102/00

(52) U.S. Cl. CPC H10K 59/122; H10K 59/1201; H10K 59/873; H10K 2102/351

(57) ABSTRACT

A display device includes: a first pixel electrode on a substrate; a pixel defining layer on the substrate, and exposing the first pixel electrode; a first light emitting layer on the first pixel electrode; a first common electrode on the first light emitting layer; a first bank on the pixel defining layer; a second bank on the first bank, and including a side surface protruding beyond a side surface of the first bank; a first inorganic layer including: a body portion on the first common electrode; and a wing portion protruding from the body portion, and spaced from a top surface of the second bank; a first enhancing layer between the wing portion of the first inorganic layer and the top surface of the second bank, and on the first inorganic layer; and an organic encapsulation layer on the first enhancing layer.

### CROSS-REFERENCE TO RELATED APPLICATION

The present application claims priority to and the benefit of Korean Patent Application No. 10-2023-0188083, filed on Dec. 21, 2023, in the Korean Intellectual Property Office, the entire disclosure of which is incorporated by reference herein.

### BACKGROUND

### 1. Field

Aspects of embodiments of the present disclosure relate to a display device, and a method for fabricating the display device.

### 2. Description of the Related Art

With the advance of information-oriented society, more and more demand is being placed on display devices for displaying images in various ways. For example, display devices are employed in various electronic devices, such as smartphones, digital cameras, laptop computers, navigation devices, and smart televisions. The display device may be a flat panel display device, such as a liquid crystal display device, a field emission display device, and an organic light emitting display device.

Among the flat panel display devices, in the light emitting display device, because each pixel of a display panel includes a light emitting element capable of emitting light by itself, an image may be displayed without a backlight unit for providing light to the display panel.

The above information disclosed in this Background section is for enhancement of understanding of the background of the present disclosure, and therefore, it may contain information that does not constitute prior art.

### SUMMARY

Recently, a display device is employed in a glass-type device for providing virtual reality and augmented reality. In order to be employed in the glass-type device, the display device may be implemented in a very small size of 2 inches or less, or may have a high pixel pitch to be implemented with a high resolution. For example, the display device may have a high pixel pitch of 400 pixels per inch (PPI) or more.

When the display device is implemented in a very small size or has a high pixel pitch, it may be difficult to implement light emitting elements that are separated for each emission area by a mask process, because the area of the emission area where the light emitting element is disposed may be reduced.

One or more embodiments of the present disclosure may be directed to a display device in which light emitting elements that are separated for each emission area are formed without a mask process.

One or more embodiments of the present disclosure may be directed to a display device having a reduced discrepancy in light emission in each pixel, which might be caused as an etchant permeates into a light emitting element in an etching process performed during a fabrication process of the display device.

However, the aspects and features of the present disclosure are not limited to those set forth herein. The above and other aspects and features of the present disclosure will become more apparent to those having ordinary skill in the art by referencing the detailed description of the present disclosure given below and the drawings.

According to one or more embodiments of the present disclosure, a display device includes: a first pixel electrode on a substrate; a pixel defining layer on the substrate, and exposing the first pixel electrode; a first light emitting layer on the first pixel electrode; a first common electrode on the first light emitting layer; a first bank on the pixel defining layer; a second bank on the first bank, and including a side surface protruding beyond a side surface of the first bank; a first inorganic layer including: a body portion on the first common electrode; and a wing portion protruding from the body portion, and spaced from a top surface of the second bank; a first enhancing layer between the wing portion of the first inorganic layer and the top surface of the second bank, and on the first inorganic layer; and an organic encapsulation layer on the first enhancing layer.

In an embodiment, the first enhancing layer may include the same thickness on the second bank and the first inorganic layer.

In an embodiment, a thickness of the first enhancing layer may be equal to or larger than 0.5 Å, and may be equal to or smaller than a distance between a bottom surface of the wing portion of the first inorganic layer and the top surface of the second bank.

In an embodiment, the first enhancing layer may include silicon oxide, aluminum oxide, zirconium oxide, hafnium oxide, cesium oxide, iron oxide, indium oxide, molybdenum oxide, or tin oxide.

In an embodiment, the display device may further include: a second pixel electrode spaced from the first pixel electrode on the substrate; a second light emitting layer on the second pixel electrode; a second common electrode on the second light emitting layer, and spaced from the first common electrode; a second inorganic layer including: a body portion on the second common electrode; and a wing portion protruding from the body portion of the second inorganic layer, and spaced from the top surface of the second bank; and a second enhancing layer between the first enhancing layer and the organic encapsulation layer, and between the wing portion of the second inorganic layer and the top surface of the second bank.

In an embodiment, a thickness of the first enhancing layer and a thickness of the second enhancing layer may be different from each other.

In an embodiment, the second bank may include a first opening overlapping with the first common electrode, and a second opening overlapping with the second common electrode. The first enhancing layer may overlap with the first opening of the second bank, and may not overlap with the second opening of the second bank.

In an embodiment, the second enhancing layer may overlap with the first opening and the second opening of the second bank.

In an embodiment, in a region where the wing portion of the second inorganic layer and the second bank overlap with each other in a thickness direction of the substrate, the second bank, the first enhancing layer, the second enhancing layer, and the wing portion of the second inorganic layer may be sequentially located on one another.

In an embodiment, the first enhancing layer, the second enhancing layer, and the organic encapsulation layer may be sequentially located on the body portion of the first inorganic layer.

In an embodiment, the second enhancing layer may be located on the body portion and the wing portion of the second inorganic layer.

In an embodiment, the second inorganic layer may be in contact with the second bank, the first enhancing layer, and the second enhancing layer.

In an embodiment, the display device may further include: a third pixel electrode spaced from the first pixel electrode and the second pixel electrode on the substrate; a third light emitting layer on the third pixel electrode; a third common electrode on the third light emitting layer, and spaced from the first common electrode and the second common electrode; and a third inorganic layer including: a body portion on the third common electrode; and a wing portion protruding from the body portion of the third inorganic layer, and spaced from the top surface of the second bank.

In an embodiment, the second bank may further include a third opening overlapping with the third common electrode, and the first enhancing layer and the second enhancing layer may not overlap with the third opening of the second bank.

In an embodiment, a bottom surface of the wing portion of the first inorganic layer may be in contact with the first enhancing layer, a bottom surface of the wing portion of the second inorganic layer may be in contact with the second enhancing layer, and a bottom surface of the wing portion of the third inorganic layer may be in contact with the organic encapsulation layer.

According to one or more embodiments of the present disclosure, a method for fabrication of a display device includes: forming a plurality of pixel electrodes spaced from each other on a substrate; forming a pixel defining layer exposing the pixel electrodes; forming a first bank on the pixel defining layer; forming a second bank protruding beyond a side surface of the first bank; forming a first light emitting layer on a first pixel electrode from among the pixel electrodes, and a first emission pattern layer on the second bank; forming a first common electrode on the first light emitting layer, and a first electrode pattern layer on the first emission pattern layer; forming a first inorganic material layer on the first common electrode; etching a part of the first inorganic material layer; etching the first emission pattern layer and the first electrode pattern layer to expose the second bank; and forming a first enhancing material layer on the second bank and the first inorganic material layer by using an atomic layer deposition (ALD) method.

In an embodiment, the etching of the first emission pattern layer and the first electrode pattern layer to expose the second bank may include removing the first emission pattern layer and the first electrode pattern layer between the second bank and the first inorganic material layer.

In an embodiment, the forming of the first light emitting layer on the first pixel electrode from among the pixel electrodes, and the first emission pattern layer on the second bank may include depositing a material on the substrate that is cut off by a protruding side surface of the second bank, and separated into the first light emitting layer and the first emission pattern layer.

In an embodiment, the method may further include: forming a second light emitting layer on a second pixel electrode from among the pixel electrodes, and a second emission pattern layer on the first enhancing material layer; forming a second common electrode on the second light emitting layer, and a second electrode pattern layer on the second emission pattern layer; forming a second inorganic material layer on the second common electrode; etching a part of the second inorganic material layer; etching the second emission pattern layer and the second electrode pattern layer to expose the first enhancing material layer; and forming a second enhancing material layer on the first enhancing material layer and the second inorganic material layer.

In an embodiment, the method may further include: forming a third light emitting layer on a third pixel electrode from among the pixel electrodes, and a third emission pattern layer on the second enhancing material layer; forming a third common electrode on the third light emitting layer, and a third electrode pattern layer on the third emission pattern layer; forming a third inorganic material layer on the third common electrode; etching a part of the third inorganic material layer; etching the third emission pattern layer and the third electrode pattern layer to expose the second enhancing material layer; and forming an organic encapsulation layer on the second enhancing material layer and the third inorganic material layer.

According to one or more embodiments of the present disclosure, by providing an enhancing layer covering the inside of an undercut of a lower inorganic encapsulation layer, moisture permeation may be prevented or substantially prevented. Further, damage to a light emitting element due to an etchant or moisture may be prevented or substantially prevented, so that discrepancy in a luminance between light emitting elements may be reduced.

However, the aspects and features of the present disclosure are not limited to those described above. Additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view illustrating a display device according to an embodiment;

FIG. 2 is a cross-sectional view of the display device of FIG. 1 when viewed from the side;

FIG. 3 is a plan view illustrating a part of a display device according to an embodiment;

FIG. 4 is a cross-sectional view illustrating a part of a display device according to an embodiment;

FIG. 5 is a cross-sectional view illustrating a light emitting element layer and a thin film encapsulation layer of a display device according to an embodiment;

FIG. 6 is a cross-sectional view showing a light emitting element layer and a thin film encapsulation layer of a display device according to another embodiment; and

FIGS. 7-24 are cross-sectional views sequentially illustrating a fabrication process of a display device according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

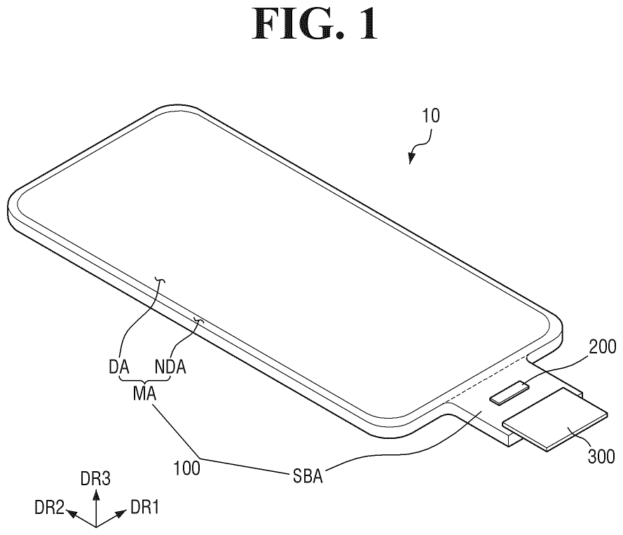

FIG. 1 is a perspective view illustrating a display device according to an embodiment.

Referring to FIG. 1, a display device 10 according to an embodiment may be included in an electronic device, and may provide a screen that is displayed on the electronic device. The electronic device may refer to any suitable electronic device for providing a display screen. Examples of the electronic device may include a television, a laptop computer, a monitor, a billboard, an Internet-of-Things device, a mobile phone, a smartphone, a tablet personal computer (PC), an electronic watch, smart glasses, a smart watch, a watch phone, a head-mounted display, a mobile communication terminal, an electronic notebook, an electronic book, a portable multimedia player (PMP), a navigation device, a game machine, a digital camera, a camcorder, and the like, which provide a display screen.

The shape of the display device 10 may be variously modified as needed or desired. For example, the display device 10 may have a shape similar to that of a rectangular shape having a short side extending in a first direction DR1 and a long side extending in a second direction DR2. An edge or a corner where the short side extending in the first direction DR1 and the long side extending in the second direction DR2 meet each other may be rounded to have a curvature, but the present disclosure is not limited thereto, and may be formed at a right angle. The planar shape of the display device 10 is not limited to a quadrilateral shape, and may be formed in another shape similar to that of another polygonal shape, a circular shape, or elliptical shape.

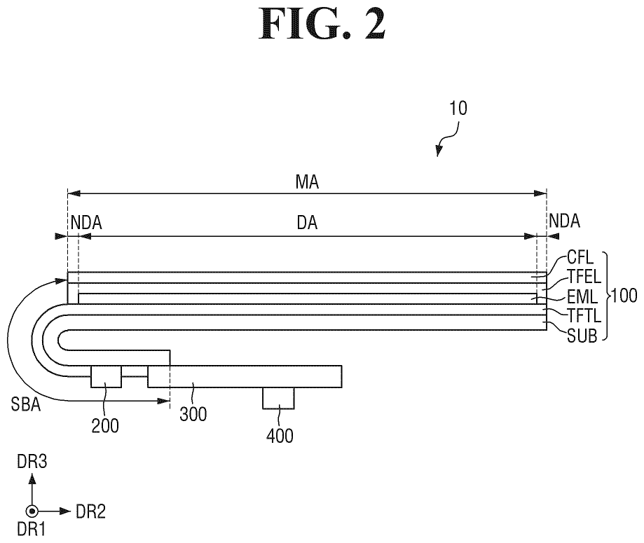

The display device 10 may include a display panel 100, a display driver 200, a circuit board 300, and a touch driver 400 (e.g., see FIG. 2).

The display panel 100 may include a main region MA and a sub-region SBA.

The main region MA may include a display area DA including pixels for displaying an image, and a non-display area NDA disposed around the display area DA. The display area DA may emit light from a plurality of emission areas or a plurality of opening areas. For example, the display panel 100 may include a pixel circuit including switching elements, a pixel defining layer for defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but the present disclosure is not limited thereto.

A plurality of pixels, a plurality of scan lines, a plurality of data lines, and a plurality of power lines may be disposed in the display area DA. Each of the plurality of pixels may be defined as a minimum unit that emits light, and each of the self-light emitting elements may correspond to a pixel from among the plurality of pixels. The plurality of scan lines may supply a scan signal received from a scan driver to the plurality of pixels. The plurality of data lines may supply the data voltages received from the display driver 200 to the plurality of pixels. The plurality of power lines may supply the power voltages received from the display driver 200 to the plurality of pixels.

The non-display area NDA may be an area outside the display area DA. The non-display area NDA may be defined as an edge area of the main region MA of the display panel 100. The non-display area NDA may include a scan driver that supplies scan signals to the scan lines, and fan-out lines that connect the display driver 200 to the display area DA.

The sub-region SBA may be a region extending from one side of the main region MA. The sub-region SBA may include a flexible material that can be bent, folded, or rolled. For example, when the sub-region SBA is bent, the sub-region SBA may overlap with the main region MA in a thickness direction (e.g., the third direction DR3). The sub-region SBA may include the display driver 200 and a pad portion connected to the circuit board 300. In another embodiment, the sub-region SBA may be omitted as needed or desired, and the display driver 200 and the pad portion may be arranged in the non-display area NDA.

The display driver 200 may output signals and voltages for driving the display panel 100. The display driver 200 may supply data voltages to data lines. The display driver 200 may supply a power voltage to the power line, and may supply a scan control signal to the scan driver. The display driver 200 may be formed as an integrated circuit (IC), and mounted on the display panel 100 by a chip on glass (COG) method, a chip on plastic (COP) method, or an ultrasonic bonding method. For example, the display driver 200 may be disposed in the sub-region SBA, and may overlap with the main region MA in the thickness direction (e.g., the third direction DR3) by bending of the sub-region SBA. As another example, the display driver 200 may be mounted on the circuit board 300.

The circuit board 300 may be attached to the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

FIG. 2 is a cross-sectional view of the display device of FIG. 1 viewed from the side. In more detail, FIG. 2 is a side view of the display device of FIG. 1, which is in a folded state.

Referring to FIG. 2, the display panel 100 may include a substrate SUB, a thin film transistor layer TFTL, a light emitting element layer EML, a thin film encapsulation layer TFEL, and a color filter layer CFL.

The substrate SUB may be a base substrate or a base member. The substrate SUB may be a flexible substrate that can be bent, folded, or rolled. For example, the substrate SUB may include a polymer resin such as polyimide (PI), but the present disclosure is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting a pixel circuit of the pixels. The thin film transistor layer TFTL may further include scan lines, data lines, power lines, scan control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, when the scan driver is formed on one side of the non-display area NDA of the display panel 100, the scan driver may include thin film transistors.

The thin film transistor layer TFTL may be disposed in the display area DA, the non-display area NDA, and the sub-region SBA. Thin film transistors, scan lines, data lines, and power lines of each of the pixels of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-region SBA.

The light emitting element layer EML may be disposed on the thin film transistor layer TFTL. The light emitting element layer EML may include a plurality of light emitting elements, each including a first electrode, a second electrode, and a light emitting layer to emit light, and a pixel defining layer defining the pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL, and the second electrode receives the cathode voltage, holes and electrons may be transferred to the organic light emitting layer through the hole transporting layer and the electron transporting layer, respectively, and may be combined with each other to emit light in the organic light emitting layer.

In another embodiment, the light emitting elements may include a quantum dot light emitting diode including a quantum dot light emitting layer, an inorganic light emitting diode including an inorganic semiconductor, or a micro light emitting diode.

The thin film encapsulation layer TFEL may cover the top surface and the side surface of the light emitting element layer EML, and may protect the light emitting element layer EML. The thin film encapsulation layer TFEL may include at least one inorganic layer and at least one organic layer for encapsulating the light emitting element layer EML.

The color filter layer CFL may be disposed on the thin film encapsulation layer TFEL. The color filter layer CFL may include a plurality of color filters corresponding to the plurality of emission areas, respectively. Each of the color filters may selectively transmit light of a desired wavelength (e.g., a specific or predetermined wavelength), and may block or absorb light of a different wavelength. The color filter layer CFL may absorb a part of light coming from the outside (e.g., external light) of the display device 10 to reduce reflected light due to external light. Accordingly, the color filter layer CFL may prevent or substantially prevent color distortion caused by reflection of the external light.

Because the color filter layer CFL may be directly disposed on the thin film encapsulation layer TFEL, the display device 10 may not use a separate substrate for the color filter layer CFL. Accordingly, the thickness of the display device 10 may be reduced (e.g., may be relatively small).

In some embodiments, the display device 10 may further include an optical device. The optical device may emit and/or receive light in infrared, ultraviolet, and/or visible light bands. For example, the optical device may be an optical sensor that detects light incident on the display device 10, such as a proximity sensor, an illuminance sensor, a camera sensor, a fingerprint sensor, or an image sensor.

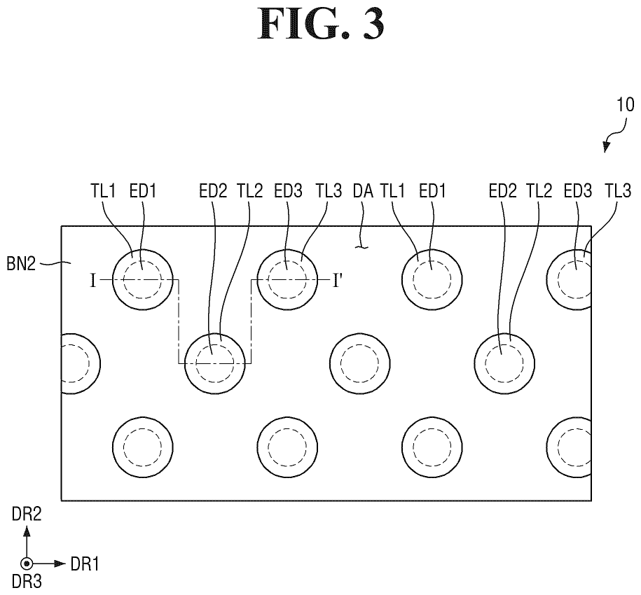

FIG. 3 is a plan view illustrating a part of a display device according to an embodiment. FIG. 3 is a plan view illustrating a layout of light emitting elements ED1, ED2, and ED3, lower inorganic encapsulation layers TL1, TL2, and TL3, and a second bank BN2 in the display area DA of the display device 10 according to an embodiment.

Referring to FIG. 3, the second bank BN2 may cover the display area DA, and may expose a part of the display area DA. Openings (e.g., indicated by dotted lines in FIG. 3) are formed in regions that are exposed without being covered with the second bank BN2, and the light emitting elements ED1, ED2, and ED3 may be disposed in the openings, respectively. The lower inorganic encapsulation layers TL1, TL2, and TL3 may cover boundaries of the openings on the second bank BN2, and may cover the light emitting elements ED1, ED2, and ED3 within the openings. The portions of the lower inorganic encapsulation layers TL1, TL2, and TL3 covering the boundaries of the openings on the second bank BN2 may be referred to as wing portions.

Although FIG. 3 illustrates that the exposed region that is not covered with the second bank BN2 is of a circular shape, the present disclosure is not limited thereto, and the exposed region may have a polygon shape, such as a triangle, a square, or a hexagon, and the shape of the lower inorganic encapsulation layers TL1, TL2, and TL3 covering the exposed region and the vicinity thereof may also be variously modified as needed or desired. A portion (e.g., a wing portion) of each of the lower inorganic encapsulation layers TL1, TL2, and TL3 may be disposed at a higher level than that of the second bank BN2, and the light emitting elements ED1, ED2, and ED3 may be disposed at a lower level than that of the second bank BN2.

The plurality of light emitting elements ED1, ED2, and ED3 may be arranged in an RGBG arrangement (e.g., a PENTILE® type arrangement, for example, such as a diamond PENTILE® type arrangement, PENTILE® being a duly registered trademark of Samsung Display Co., Ltd.). For example, the first light emitting element ED1 and the third light emitting element ED3 may be disposed to be spaced apart from each other in the first direction DR1, and may be alternately disposed along the first direction DR1 and the second direction DR2. The second light emitting element ED2 may be spaced apart from other adjacent second light emitting elements ED2 in the first direction DR1 and the second direction DR2. The second light emitting element ED2 and the first light emitting element ED1, or the second light emitting element ED2 and the third light emitting element ED3, may be alternately arranged along any suitable direction on a plane formed by the first direction DR1 and the second direction DR2. The shape and the layout of the plurality of light emitting elements and the exposed regions that are not covered with the second bank BN2 are not limited to those illustrated in FIG. 3.

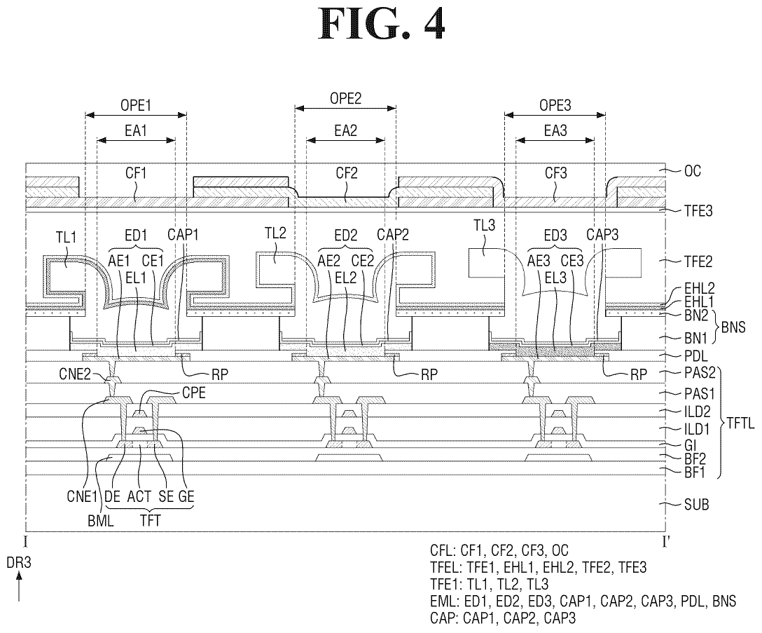

FIG. 4 is a cross-sectional view illustrating a part of a display device according to an embodiment. In more detail, FIG. 4 is a cross-sectional view taken along the line I-I′ of FIG. 3, and shows cross sections of the substrate SUB, the thin film transistor layer TFTL, the light emitting element layer EML, the thin film encapsulation layer TFEL, and the color filter layer CFL.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic layer capable of preventing or substantially preventing penetration of air and/or moisture. For example, the first buffer layer BF1 may include a plurality of inorganic layers that are alternately stacked.

The lower metal layer BML may be disposed on the first buffer layer BF1. For example, the lower metal layer BML may be formed as a single layer or multiple layers including (e.g., made of) any one or more of molybdenum (Mo), aluminum (Al), chromium (Cr), gold (Au), titanium (Ti), nickel (Ni), neodymium (Nd), copper (Cu), or a suitable alloy thereof.

The second buffer layer BF2 may cover the first buffer layer BF1 and the lower metal layer BML. The second buffer layer BF2 may include an inorganic layer capable of preventing or substantially preventing penetration of air and/or moisture. For example, the second buffer layer BF2 may include a plurality of inorganic layers that are alternately stacked.

The thin film transistor TFT may be disposed on the second buffer layer BF2, and may constitute a pixel circuit of a corresponding one of a plurality of pixels. For example, the thin film transistor TFT may be a switching transistor or a driving transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap with the lower metal layer BML and the gate electrode GE in the thickness direction DR3, and may be insulated from the gate electrode GE by the gate insulating layer GI. In a part of the semiconductor layer ACT, a material of the semiconductor layer ACT may be made into a conductor to form the source electrode SE and the drain electrode DE.

The gate electrode GE may be disposed on the gate insulating layer GI. The gate electrode GE may overlap with the semiconductor layer ACT in the thickness direction DR3, with the gate insulating layer GI interposed therebetween.

The gate insulating layer GI may be disposed on the semiconductor layer ACT. For example, the gate insulating layer GI may cover the semiconductor layer ACT and the second buffer layer BF2 to insulate the gate electrode GE from the semiconductor layer ACT. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and the contact hole of the second interlayer insulating layer ILD2.

The capacitor electrode CPE may be disposed on the first interlayer insulating layer ILD1. The capacitor electrode CPE may overlap with the gate electrode GE in the thickness direction DR3. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT to the second connection electrode CNE2. The first connection electrode CNE1 may be inserted into a contact hole provided in the second interlayer insulating layer ILD2, the first interlayer insulating layer ILD1, and the gate insulating layer GI to be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 to pixel electrodes AE1, AE2, and AE3 of the light emitting elements ED1, ED2, and ED3. The second connection electrode CNE2 may be inserted into a contact hole formed in the first passivation layer PAS1 to be in contact with the first connection electrode CNE1.

The second passivation layer PAS2 may cover the second connection electrode CNE2 and the first passivation layer PAS1. The second passivation layer PAS2 may include a contact hole through which the pixel electrodes AE1, AE2, and AE3 of the light emitting elements ED1, ED2, and ED3 pass.

The light emitting element layer EML may be disposed on the thin film transistor layer TFTL. The light emitting element layer EML may include the light emitting elements ED1, ED2, and ED3, a pixel defining layer PDL, a capping layer CAP, and a bank structure BNS. The light emitting elements ED1, ED2, and ED3 may include the pixel electrodes AE1, AE2, and AE3, light emitting layers EL1, EL2, and EL3, and common electrodes CE1, CE2, and CE3.

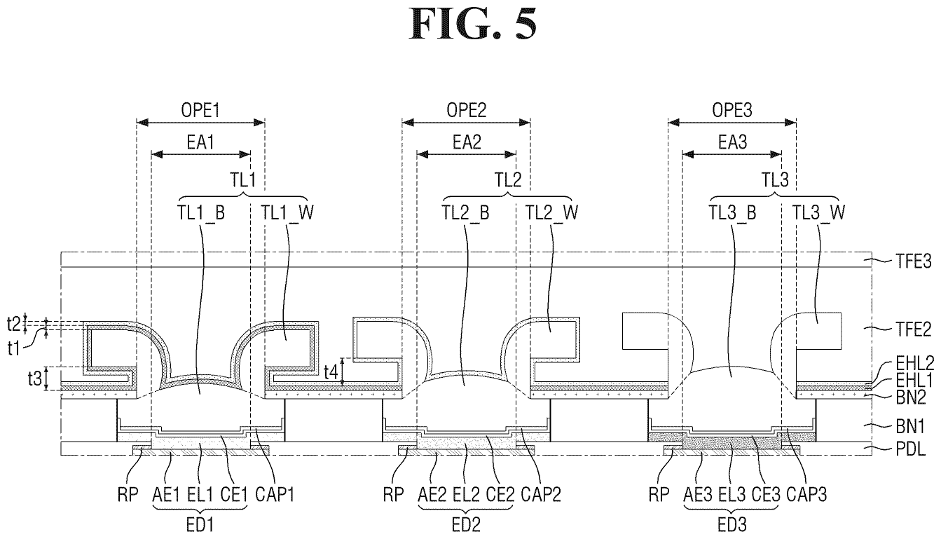

FIG. 5 is a cross-sectional view illustrating the light emitting element layer EML and the thin film encapsulation layer TFEL in the display area DA of a display device according to an embodiment. In more detail, FIG. 5 is a cross-sectional view showing the light emitting element layer EML of FIG. 4.

Referring to FIG. 5 in addition to FIG. 4, the display device 10 may include a plurality of emission areas EA1, EA2, and EA3 disposed in the display area DA. The emission areas EA1, EA2, and EA3 may be defined as areas in which the pixel electrodes AE1, AE2, and AE3, the light emitting layers EL1, EL2, and EL3, and the common electrodes CE1, CE2, and CE3 overlap with each other in the thickness direction of the substrate SUB. The emission areas EA1, EA2, and EA3 may include areas in which light is emitted from the light emitting elements ED1, ED2, and ED3, where the pixel electrodes AE1, AE2, and AE3, the light emitting layers EL1, EL2, and EL3, and the common electrodes CE1, CE2, and CE3 are sequentially stacked, to travel in the third direction DR3 towards the color filter layer CFL. The emission areas EA1, EA2, and EA3 may include the first emission area EA1, the second emission area EA2, and the third emission area EA3 that are spaced apart from each other and for emitting light of the same or different colors as/from each other.

In an embodiment, the areas or sizes of the first to third emission areas EA1, EA2, and EA3 may be the same or substantially the same as each other. For example, in the display device 10, the first emission area EA1, the second emission area EA2, and the third emission area EA3 may have the same or substantially the same area as each other. However, the present disclosure is not limited thereto. In the display device 10, the areas or sizes of the first to third emission areas EA1, EA2, and EA3 may be different from each other. For example, the area of the second emission area EA2 may be greater than the areas of the first emission area EA1 and the third emission area EA3, and the area of the third emission area EA3 may be greater than the area of the first emission area EA1. The intensity of light emitted from the corresponding emission areas EA1, EA2, and EA3 may vary according to the areas of the emission areas EA1, EA2, and EA3, and the areas of the emission areas EA1, EA2, and EA3 may be adjusted to control the color of the screen displayed on the display device 10. While FIG. 4 shows that the emission areas EA1, EA2, and EA3 have the same or substantially the same area as each other, the present disclosure is not limited thereto.

In the display device 10, one first emission area EA1, one second emission area EA2, and one third emission area EA3 that are disposed adjacent to each other may form one pixel group. One pixel group may include the emission areas EA1, EA2, and EA3 for emitting light of different colors from each other to express a white gray scale. However, the present disclosure is not limited thereto, and the combination of the emission areas EA1, EA2, and EA3 constituting one pixel group may be variously modified as needed or desired, for example, depending on the arrangement of the emission areas EA1, EA2, and EA3, the color of the light emitted from the emission areas EA1, EA2, and EA3, and the like.

A plurality of openings OPE1, OPE2, and OPE3 may be formed in the bank structure BNS of the light emitting element layer EML, and may be defined along the boundary of the bank structure BNS. The second bank BN2 may include the openings OPE1, OPE2, and OPE3 overlapping with the light emitting elements ED1, ED2, and ED3, respectively, and each of the openings OPE1, OPE2, and OPE3 may include a corresponding one of the emission areas EA1, EA2, and EA3.

The display device 10 may include the plurality of light emitting elements ED1, ED2, and ED3 disposed in the different emission areas EA1, EA2, and EA3. The light emitting elements ED1, ED2, and ED3 may include the first light emitting element ED1 disposed in the first emission area EA1, the second light emitting element ED2 disposed in the second emission area EA2, and the third light emitting element ED3 disposed in the third emission area EA3.

The light emitting elements ED1, ED2, and ED3 may respectively include the pixel electrodes AE1, AE2, and AE3, the light emitting layers EL1, EL2, and EL3, and the common electrodes CE1, CE2, and CE3, and the light emitting elements ED1, ED2, and ED3 disposed in the different emission areas EA1, EA2, and EA3 may emit light of different colors from each other depending on the materials of the light emitting layers EL1, EL2, and EL3. For example, the first light emitting element ED1 disposed in the first emission area EA1 may emit first light of a red color having a peak wavelength within a range of 610 nm to 650 nm. The second light emitting element ED2 disposed in the second emission area EA2 may emit second light of a green color having a peak wavelength within a range of 510 nm to 550 nm. The third light emitting element ED3 disposed in the third emission area EA3 may emit third light of a blue color having a peak wavelength within a range of 440 nm to 480 nm. The first to third emission areas EA1, EA2, and EA3 constituting one pixel may respectively include the light emitting elements ED1, ED2, and ED3 for emitting light of different colors from each other to express a white gray scale. As another example, the light emitting layers EL1, EL2, and EL3 may include two or more materials for emitting light of different colors from each other, so that one light emitting layer may emit mixed light. For example, the light emitting layers EL1, EL2, and EL3 may include a red light emitting material and a green light emitting material to emit yellow light, or may include the red light emitting material, the green light emitting material, and a blue light emitting material to emit white light.

The pixel electrodes AE1, AE2, and AE3 may be disposed on the second passivation layer PAS2. The pixel electrodes AE1, AE2, and AE3 may be disposed in the plurality of emission areas EA1, EA2, and EA3, respectively. The pixel electrodes AE1, AE2, and AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be disposed to be spaced apart from each other on the second passivation layer PAS2.

The pixel electrodes AE1, AE2, and AE3 may be electrically connected to the drain electrodes DE of the thin film transistors TFT through the first and second connection electrodes CNE1 and CNE2. The edges of the pixel electrodes AE1, AE2, and AE3 that are spaced apart from each other may be covered by the pixel defining layer PDL, so that the first to third pixel electrodes AE1, AE2, and AE3 may be insulated from each other.

The pixel electrodes AE1, AE2, and AE3 may include a transparent electrode material and/or a conductive metal material. The metal material may be at least one of silver (Ag), copper (Cu), aluminum (Al), nickel (Ni), lanthanum (La), titanium (Ti), or titanium nitride (TIN). The transparent electrode material may be at least one of indium tin oxide (ITO), indium zinc oxide (IZO), or indium tin zinc oxide (ITZO). The pixel electrodes AE1, AE2, and AE3 may have a multilayered structure of a transparent electrode material and a conductive metal material.

The pixel defining layer PDL may be disposed on the second passivation layer PAS2, a residual pattern RP, and the pixel electrodes AE1, AE2, and AE3. The pixel defining layer PDL may be disposed on the entire or substantially entire second passivation layer PAS2, and may cover the side surfaces of the pixel electrodes AE1, AE2, and AE3 and the residual pattern RP to partially expose top surfaces of the pixel electrodes AE1, AE2, and AE3. For example, the pixel defining layer PDL may expose the first pixel electrode AE1 in the first emission area EA1, and a first light emitting layer EL1 may be directly disposed on the first pixel electrode AE1.

The pixel defining layer PDL may include an inorganic insulating material. The pixel defining layer PDL may include at least one of a silicon nitride layer, a silicon oxynitride layer, a silicon oxide layer, a titanium oxide layer, an aluminum oxide layer, tantalum oxide, hafnium oxide, zinc oxide, or an amorphous silicon layer, but the present disclosure is not limited thereto.

In accordance with an embodiment, the pixel defining layer PDL may be disposed on the pixel electrodes AE1, AE2, and AE3, and may be spaced apart from the top surfaces of the pixel electrodes AE1, AE2, and AE3. The pixel defining layer PDL may partially overlap with the top surfaces of the pixel electrodes AE1, AE2, and AE3 in the thickness direction DR3 of the substrate SUB, but may not be in direct contact with the top surfaces of the pixel electrodes AE1, AE2, and AE3. The residual pattern RP may be disposed between the pixel defining layer PDL and the pixel electrodes AE1, AE2, and AE3. However, the pixel defining layer PDL may be in direct contact with the side surfaces of the pixel electrodes AE1, AE2, and AE3. The side surface of the pixel defining layer PDL may protrude more toward the emission areas EA1, EA2, and EA3 than the side surface of the second bank BN2 (e.g., in a plan view).

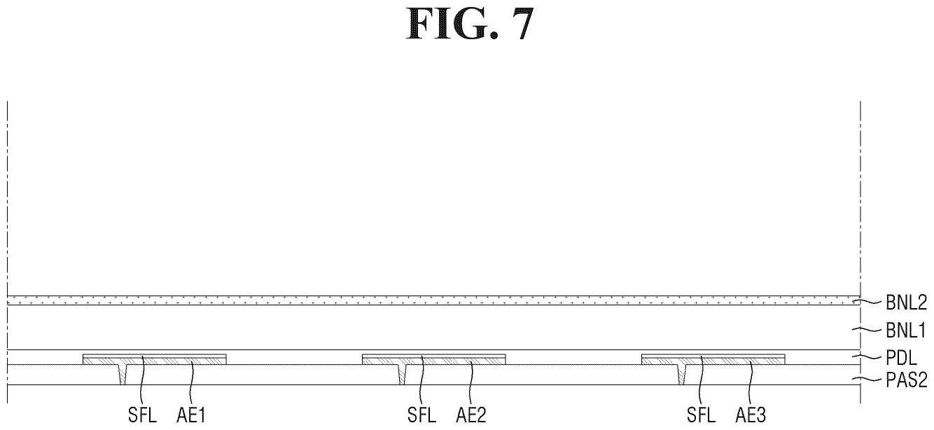

The residual pattern RP may be disposed on the edge of each of the pixel electrodes AE1, AE2, and AE3. The pixel defining layer PDL may not be in direct contact with the top surfaces of the pixel electrodes AE1, AE2, and AE3 due to the residual pattern RP. The residual pattern RP may be formed by removing a part of a sacrificial layer SFL (e.g., see FIG. 7) disposed on the pixel electrodes AE1, AE2, and AE3 in a fabrication process of the display device 10. The residual pattern RP may include a metal or an oxide semiconductor material. In the drawings, the side surface of the residual pattern RP facing the emission areas EA1, EA2, and EA3 is illustrated as being aligned with the side surface of the pixel defining layer PDL, but the present disclosure is not limited thereto. The side surface of the residual pattern RP may protrude beyond the side surface of the pixel defining layer PDL farther toward the emission areas EA1, EA2, and EA3, or may be recessed as compared to the side surface of the pixel defining layer PDL. The side surface of the pixel defining layer PDL may be a side surface positioned at the outermost side toward the emission areas EA1, EA2, and EA3.

The light emitting layers EL1, EL2, and EL3 may be disposed on the pixel electrodes AE1, AE2, and AE3, respectively. The light emitting layers EL1, EL2, and EL3 may be organic light emitting layers including (e.g., made of) an organic material, and may be formed on the pixel electrodes AE1, AE2, and AE3, respectively, by the deposition process. The light emitting layers EL1, EL2, and EL3 may have a multilayered structure, and each of a hole injection material, a hole transport material, a light emitting material, an electron transport material, and/or an electron injection material may form a layer. When the thin film transistor TFT applies a voltage (e.g., a predetermined voltage) to the pixel electrodes AE1, AE2, and AE3 of the light emitting elements ED1, ED2, and ED3, and the common electrodes CE1, CE2, and CE3 of the light emitting elements ED1, ED2, and ED3 receive a common voltage or a cathode voltage, holes and electrons may be injected and transported, and may be combined with each other to emit light in the light emitting layers EL1, EL2, and EL3.

The light emitting layers EL1, EL2, and EL3 may include the first light emitting layer EL1, the second light emitting layer EL2, and the third light emitting layer EL3 disposed in the different emission areas EA1, EA2, and EA3. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. The plurality of light emitting layers EL1, EL2, and EL3 may emit light of different colors from each other, or one light emitting layer EL1, EL2, and EL3 may emit mixed light. In an embodiment, the first light emitting layer EL1 may emit red light, the second light emitting layer EL2 may emit green light, and the third light emitting layer EL3 may emit blue light. In another embodiment, the first light emitting layer EL1 may emit yellow light that is mixed light of red light and green light, and the second light emitting layer EL2 may emit blue light. In another embodiment, the first light emitting layer EL1 may emit white light, which is a mixture of red light, green light, and blue light.

The light emitting layers EL1, EL2, and EL3 may be disposed on the top surface of the pixel defining layer PDL. In an embodiment, the side surface of the residual pattern RP may be depressed compared to the side surface of the pixel defining layer PDL, and portions of the light emitting layers EL1, EL2, and EL3 may be disposed in a space between the pixel electrodes AE1, AE2, and AE3 and the pixel defining layer PDL. In an embodiment, the light emitting layers EL1, EL2, and EL3 may be in contact with the pixel defining layer PDL, the residual pattern RP, and the pixel electrodes AE1, AE2, and AE3.

The common electrodes CE1, CE2, and CE3 may be disposed on the light emitting layers EL1, EL2, and EL3, respectively. The common electrodes CE1, CE2, and CE3 may include a transparent conductive material, so that the light generated in the light emitting layers EL1, EL2, and EL3 may be emitted. The common electrodes CE1, CE2, and CE3 may receive a common voltage or a low potential voltage. When the pixel electrodes AE1, AE2, and AE3 receive the voltage corresponding to a data voltage and the common electrodes CE1, CE2, and CE3 receive the low potential voltage, a potential difference is formed between the pixel electrodes AE1, AE2, and AE3 and the common electrodes CE1, CE2, and CE3, so that the light emitting layers EL1, EL2, and EL3 may emit light.

The common electrodes CE1, CE2, and CE3 may include a first common electrode CE1, a second common electrode CE2, and a third common electrode CE3 disposed in the different emission areas EA1, EA2, and EA3. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3. The first to third common electrodes CE1, CE2, and CE3 may be spaced apart from each other.

Capping layers CAP1, CAP2, and CAP3 may be disposed on the common electrodes CE1, CE2, and CE3, respectively. The capping layers CAP1, CAP2, and CAP3 may include an organic or inorganic insulating material to cover patterns disposed on the light emitting elements ED1, ED2, and ED3. The capping layers CAP1, CAP2, and CAP3 may prevent or substantially prevent the light emitting elements ED1, ED2, and ED3 from being damaged by external air. In an embodiment, the capping layers CAP1, CAP2, and CAP3 may include an organic material, such as a-NPD, NPB, TPD, m-MTDATA, Alq₃, LiF, and/or CuPc, or an inorganic material, such as aluminum oxide, titanium oxide, tantalum oxide, hafnium oxide, zinc oxide, silicon oxide, silicon nitride, and/or silicon oxynitride.

The capping layers CAP1, CAP2, and CAP3 may include a first capping layer CAP1, a second capping layer CAP2, and a third capping layer CAP3 disposed in the different emission areas EA1, EA2, and EA3, respectively. The first to third capping layers CAP1, CAP2, and CAP3 may be spaced apart from each other.

The display device 10 may include the plurality of bank structures BNS disposed on the pixel defining layer PDL. The bank structure BNS may have a structure in which the first and second banks BN1 and BN2 including different materials from each other are sequentially stacked. The bank structure BNS may include the plurality of openings including the emission areas EA1, EA2, and EA3, and may be disposed to overlap with the light blocking area of the color filter layer CFL to be described in more detail below. The light emitting elements ED1, ED2, and ED3 of the display device 10 may be disposed to overlap with the openings OPE1, OPE2, and OPE3 of the bank structure BNS.

The first bank BN1 may be disposed on the pixel defining layer PDL. The side surface of the first bank BN1 may be recessed more than the side surface of the pixel defining layer PDL in a direction opposite to the direction facing the emission areas EA1, EA2, and EA3. The side surface of the first bank BN1 may be recessed more than the side surface of the second bank BN2 to be described in more detail below in the direction opposite to the direction facing the emission areas EA1, EA2, and EA3.

In accordance with an embodiment, the first bank BN1 may include a metal material. In an embodiment, the first bank BN1 may include aluminum (Al), an oxide of aluminum (Al), or an alloy of aluminum (Al).

In accordance with an embodiment, the common electrodes CE1, CE2, and CE3 may be in direct contact with the side surface of the first bank BN1. One ends and the other ends of the common electrodes CE1, CE2, and CE3 may be in contact with the side surface of the first bank BN1. The common electrodes CE1, CE2, and CE3 of the different light emitting elements ED1, ED2, and ED3 may be in direct contact with the first bank BN1, and the first bank BN1 may include a metal material. Thus, the common electrodes CE1, CE2, and CE3 may be electrically connected to each other through the first bank BN1.

The light emitting layers EL1, EL2, and EL3 may be in direct contact with the side surface of the first bank BN1. The contact area between the common electrodes CE1, CE2, and CE3 and the side surface of the first bank BN1 may be greater than the contact area between the light emitting layers EL1, EL2, and EL3 and the side surface of the first bank BN1. The common electrodes CE1, CE2, and CE3 may be disposed in larger areas on the side surface of the first bank BN1 compared to the light emitting layers EL1, EL2, and EL3, or may be disposed at higher positions on the side surface of the first bank BN1 compared to the light emitting layers EL1, EL2, and EL3. Because the common electrodes CE1, CE2, and CE3 of the different light emitting elements ED1, ED2, and ED3 are electrically connected to each other through the first bank BN1, they may be in contact with the first bank BN1 in larger areas according to some embodiments.

The first bank BN1 may have a top surface at a position higher than those of the common electrodes CE1, CE2, and CE3 and the capping layers CAP1, CAP2, and CAP3. The height from the substrate SUB to the top surface of the first bank BN1 may be larger than the height from the substrate SUB to the common electrodes CE1, CE2, and CE3.

The second bank BN2 may be disposed on the first bank BN1. The second bank BN2 may include the openings OPE1, OPE2, and OPE3 overlapping with the emission areas EA1, EA2, and EA3, respectively, and each of the openings may be defined by a side surface. The second bank BN2 may include a tip or eave, which is an area protruding more compared to the first bank BN1. The side surface of the second bank BN2 may protrude more toward the emission areas EA1, EA2, and EA3 than the side surface of the first bank BN1.

As the side surface of the second bank BN2 has a shape protruding more toward the emission areas EA1, EA2, and EA3 than the side surface of the first bank BN1, an undercut structure of the first bank BN1 may be formed under the tip of the second bank BN2.

In the display device 10 according to an embodiment, because the bank structure BNS includes the tip protruding toward the emission areas EA1, EA2, and EA3, the light emitting layers EL1, EL2, and EL3 and the common electrodes CE1, CE2, and CE3 that are spaced apart from each other may be formed through deposition and etching processes instead of a mask process. Further, it may be possible to individually form different layers in the different emission areas EA1, EA2, and EA3 by the deposition process. For example, even when the light emitting layers EL1, EL2, and EL3 of the light emitting elements ED1, ED2, and ED3 and the common electrodes CE1, CE2, and CE3 are formed by a deposition process using no mask, the deposited materials may be cut off (e.g., separated) with the bank structure BNS interposed therebetween by the tip of the second bank BN2, without being connected between the emission areas EA1, EA2, and EA3. By a process of forming a material for forming a specific layer on the entire surface of the display device 10, and then removing the layer formed in an undesired region by etching, it is possible to individually form different layers in the different emission areas EA1, EA2, and EA3. In the display device 10, the different light emitting elements ED1, ED2, and ED3 may be formed in the different emission areas EA1, EA2, and EA3 by the deposition and etching process without using the mask process, and an unnecessary component in the display device 10 may be omitted to minimize or reduce the area of the non-display area NDA.

The second bank BN2 may include a metal material different from the metal material of the first bank BN1. In more detail, the metal material of the second bank BN2 may be a material that is removed by dry etching together with the metal material of the first bank BN1, but may have an etching rate slower (e.g., much slower) than that of the first bank BN1 when wet-etched, or is not etched by wet etching. In an embodiment, the first bank BN1 may include aluminum (Al), an oxide of aluminum (Al), or an alloy of aluminum (Al), and the second bank BN2 may include titanium (Ti), an oxide of titanium (Ti), or an alloy of titanium (Ti).

The tip of the second bank BN2 may overlap with the common electrodes CE1, CE2, and CE3 in the direction DR3 perpendicular to or substantially perpendicular to the substrate SUB. Further, the tip of the second bank BN2 may overlap with the light emitting layers EL1, EL2, and EL3 in the direction DR3 perpendicular to or substantially perpendicular to the substrate SUB. Further, the tip of the second bank BN2 may overlap with the pixel defining layer PDL in the direction DR3 perpendicular to or substantially perpendicular to the substrate SUB. The common electrodes CE1, CE2, and CE3 may be formed under the bottom surface of the tip of the second bank BN2. One end and the other end of each of the common electrodes CE1, CE2, and CE3 may overlap with the second bank BN2 in the thickness direction DR3 of the substrate. The maximum vertical distance from the substrate SUB to the common electrodes CE1, CE2, and CE3 may be smaller than the maximum vertical distance from the substrate SUB to the first bank BN1.

The thin film encapsulation layer TFEL may be disposed on the light emitting elements ED1, ED2, and ED3 and the bank structure BNS, and may cover the plurality of light emitting elements ED1, ED2, and ED3 and the bank structure BNS. The thin film encapsulation layer TFEL may include at least one inorganic layer to prevent oxygen and/or moisture from permeating into the light emitting element layer EML. The thin film encapsulation layer TFEL may include at least one organic layer to protect the light emitting element layer EML from foreign substances, such as dust.

In an embodiment, the thin film encapsulation layer TFEL may include a lower inorganic encapsulation layer TFE1, a first enhancing layer EHL1, a second enhancing layer EHL2, an organic encapsulation layer TFE2, and an upper inorganic encapsulation layer TFE3, which are sequentially stacked.

Each of the lower inorganic encapsulation layer TFE1 and the upper inorganic encapsulation layer TFE3 may include one or more inorganic insulators (e.g., one or more inorganic insulating materials). The inorganic insulating material may be any one of silicon oxide, silicon nitride, and/or silicon oxynitride, and may include, for example, aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. Examples of the polymer-based material may include acrylic resin, epoxy resin, polyimide, polyethylene, and the like. For example, the organic encapsulation layer TFE2 may include an acrylic resin, for example, such as polymethyl methacrylate, polyacrylic acid, or the like. The organic encapsulation layer TFE2 may be formed by curing a monomer or applying a polymer.

The lower inorganic encapsulation layer TFE1 may be disposed on the light emitting elements ED1, ED2, and ED3, and the bank structure BNS. The lower inorganic encapsulation layer TFE1 may include a first inorganic layer TL1, a second inorganic layer TL2, and a third inorganic layer TL3 disposed to correspond to the different emission areas EA1, EA2, and EA3, respectively. The first inorganic layer TL1, the second inorganic layer TL2, and the third inorganic layer TL3 may include an inorganic insulating material to cover the light emitting elements ED1, ED2, and ED3, respectively. The first inorganic layer TL1, the second inorganic layer TL2, and the third inorganic layer TL3 may prevent or substantially prevent the light emitting elements ED1, ED2, and ED3 from being damaged by external air.

Because the lower inorganic encapsulation layer TFE1 (e.g., TL1, TL2, TL3) may be formed through a chemical vapor deposition (CVD) method, it may be formed along a stepped portion of a layer to be deposited. For example, the first inorganic layer TL1, the second inorganic layer TL2, and the third inorganic layer TL3 may form thin films even under the undercut by the tip of the bank structure BNS. The lower inorganic encapsulation layers TL1, TL2, and TL3 may be disposed along the top, side, and bottom surfaces of the second bank BN2, the side surface of the first bank BN1, and the top surfaces of the common electrodes CE1, CE2, and CE3.

The first inorganic layer TL1 may not overlap with the second opening OPE2 and the third opening OPE3, and may be disposed on (e.g., only on) the first opening OPE1, the first light emitting element ED1, and the bank structure BNS in the periphery thereof. The second inorganic layer TL2 may not overlap with the first opening OPE1 and the third opening OPE3, and may be disposed on (e.g., only on) the second opening OPE2, the second light emitting element ED2, and the bank structure BNS in the periphery thereof. The third inorganic layer TL3 may not overlap with the first opening OPE1 and the second opening OPE2, and may be disposed on (e.g., only on) the third opening OPE3, the third light emitting element ED3, and the bank structure BNS in the periphery thereof.

The first inorganic layer TL1 may be formed after the first common electrode CE1 is formed. The second inorganic layer TL2 may be formed after the second common electrode CE2 is formed. The third inorganic layer TL3 may be formed after the third common electrode CE3 is formed. The first inorganic layer TL1, the second inorganic layer TL2, and the third inorganic layer TL3 may be spaced apart from each other on the bank structure BNS.

The lower inorganic encapsulation layers TL1, TL2, and TL3 may include body portions TL1_B, TL2_B, and TL3_B surrounded (e.g., around peripheries thereof) by the bank structure BNS, and wing portions TL1_W, TL2_W, and TL3_W protruding from the body portions and spaced apart from the top surface of the second bank BN2.

The body portions TL1_B, TL2_B, and TL3_B of the lower inorganic encapsulation layers TL1, TL2, and TL3 may cover the bottom surface of the second bank BN, the side surface of the first bank BN1, the capping layers CAP1, CAP2, and CAP3, and the common electrodes CE1, CE2, and CE3, and may include portions surrounded (e.g., around peripheries thereof) by the bank structure BNS.

The wing portions TL1_W, TL2_W, and TL3_W of the lower inorganic encapsulation layers TL1, TL2, and TL3 may be disposed on the side and top surfaces of the second bank BN2. The wing portions TL1_W, TL2_W, and TL3_W of the lower inorganic encapsulation layers TL1, TL2, and TL3 may be spaced apart from the top surface of the second bank BN2, and each of the wing portions TL1_W, TL2_W, and TL3_W may have a bottom surface facing the top surface of the second bank BN2. Each of the wing portions TL1_W, TL2_W, and TL3_W of the lower inorganic encapsulation layers TL1, TL2, and TL3 may have an undercut structure below the bottom surface thereof, and may include a first side surface and a second side surface in the undercut structure. The first side surfaces of the wing portions TL1_W, TL2_W, and TL3_W of the lower inorganic encapsulation layers TL1, TL2, and TL3 may be adjacent to or aligned with the side surface of the second bank BN2 under the bottom surfaces of the wing portions TL1_W, TL2_W, and TL3_W, and may not overlap with the first bank BN1. The second side surfaces of the wing portions TL1_W, TL2_W, and TL3_W of the lower inorganic encapsulation layers TL1, TL2, and TL3 may be disposed above the bottom surfaces of the wing portions TL1_W, TL2_W, and TL3_W, and may overlap with the first bank BN1.

An enhancing layer EHL may be disposed on the lower inorganic layers TL1, TL2, and TL3, and may cover the undercut structure of the lower inorganic layers TL1, TL2, and TL3. The enhancing layer EHL may include the first enhancing layer EHL1 disposed on the first inorganic layer TL1, and the second enhancing layer EHL2 disposed on the second inorganic layer TL2. The enhancing layers EHL1 and EHL2 may prevent or substantially prevent the first inorganic layer TL1 and the second inorganic layer TL2 from being deformed or separated from the tip of the second bank BN2 during an etching or cleaning process after the formation of the first inorganic layer TL1 and the second inorganic layer TL2. The enhancing layers EHL1 and EL2 may increase the encapsulation effect of the lower inorganic encapsulation layers TL1, TL2, and TL3. As an example, the enhancing layer EHL may be formed by atomic layer deposition (ALD) having excellent step coverage, and may have a thin thickness while covering the undercut structure of the lower inorganic layers TL1, TL2, and TL3.

The first enhancing layer EHL1 may be disposed on the first inorganic layer TL1 and the second bank BN2. The first enhancing layer EHL1 may cover the undercut structure of the first inorganic layer TL1, as well as a clearance space between the wing portion TL1_W of the first inorganic layer TL1 and the second bank BN2. In more detail, the first enhancing layer EHL1 may cover the first side surface and the bottom surface of the wing portion TL1_W of the first inorganic layer TL1, as well as the top surface of the second bank BN2. In an undercut area of the first inorganic layer TL1, or in other words, in an area in which the wing portion TL1_W of the first inorganic layer TL1 overlaps with the second bank BN2 in the thickness direction DR3 of the substrate SUB, the second bank BN2, the first enhancing layer EHL1, and the wing portion TL1_W of the first inorganic layer TL1 may be sequentially disposed. Depending on the thickness of the first enhancing layer EHL1, the second enhancing layer EHL2 and the organic encapsulation layer TFE2 may be additionally disposed between the first enhancing layer EHL1 and the wing portions TL1_W of the first inorganic layer TL1.

The first enhancing layer EHL1 may be formed after the formation of the first inorganic layer TL1. The first enhancing layer EHL1 may overlap with the first opening OPE1 and the first emission area EA1, and may not overlap with the second opening OPE2, the second emission area EA2, the third opening OPE3, and the third emission area EA3.

The second enhancing layer EHL2 may be disposed on the second inorganic layer TL2 and the first enhancing layer EHL1. The second enhancing layer EHL2 may cover the undercut structure of the second inorganic layer TL2, as well as a clearance space between the wing portion TL2_W of the second inorganic layer TL2 and the first enhancing layer EHL1. In more detail, the second enhancing layer EHL2 may cover the first side surface and the bottom surface of the wing portion TL2_W of the second inorganic layer TL2, as well as the top surface of the first enhancing layer EHL1. In an undercut area of the second inorganic layer TL2, or in other words, in an area in which the wing portion TL2_W of the second inorganic layer overlaps with the second bank BN2 in the thickness direction DR3 of the substrate SUB, the second bank BN2, the first enhancing layer EHL1, the second enhancing layer EHL2, and the wing portion TL2_W of the second inorganic layer TL2 may be sequentially disposed.

The second enhancing layer EHL2 may be formed after the formation of the second inorganic layer TL2, so it may be formed on the first enhancing layer EHL1 as well. The second enhancing layer EHL2 may overlap with the first opening OPE1, the first emission area EA1, the second opening OPE2, and the second emission area EA2, but it may not overlap with the third opening OPE3 and the third emission area EA3.

The wing portions TL1_W, TL2_W, and TL3_W of the lower inorganic encapsulation layers TL1, TL2, and TL3 may be covered with different layers, and the heights of their bottom surfaces may be different from each other. The bottom surface of the wing portion TL2_W of the second inorganic layer TL2 may be located at a higher level than that of the bottom surface of the wing portion TL1_W of the first inorganic layer TL1. The bottom surface of the wing portion TL3_W of the third inorganic layer TL3 may be located at a higher level than that of the bottom surface of the wing portion TL2_W of the second inorganic layer TL2.

The wing portion TL1_W of the first inorganic layer TL1 may be covered with the first enhancing layer EHL1. A bottom surface and a first side surface of the wing portion TL1_W of the first inorganic layer TL1 may be in contact with the first enhancing layer EHL1. The first inorganic layer TL1 may be in contact with the first enhancing layer EHL1, the second bank BN2, and the first bank BN1. The first enhancing layer EHL1, the second enhancing layer EHL2, and the organic encapsulation layer TFE2 may be sequentially disposed on the body portion TL1_B of the first inorganic layer TL1.

The wing portion TL2_W of the second inorganic layer TL2 may be covered with the second enhancing layer EHL2. The bottom surface and the first side surface of the wing portion TL2_W of the second inorganic layer TL2 may be in contact with the second enhancing layer EHL2. The second inorganic layer TL2 may be in contact with the first enhancing layer EHL1, the second enhancing layer EHL2, the second bank BN2, and the first bank BN1. The second enhancing layer EHL2 and the organic encapsulation layer TFE2 may be sequentially disposed on the body portion TL1_B of the first inorganic layer TL1.

The wing portion TL3_W of the third inorganic layer TL3 may be covered with the organic encapsulation layer TFE2. The bottom surface and the first side surface of the wing portion TL3_W of the third inorganic layer TL3 may be in contact with the organic encapsulation layer TFE2. The third inorganic layer TL3 may be in contact with the first enhancing layer EHL1, the second enhancing layer EHL2, the organic encapsulation layer TFE2, the second bank BN2, and the first bank BN1. In an undercut area of the third inorganic layer TL3, or in other words, in an area in which the wing portion TL3_W of the third inorganic layer overlaps with the second bank BN2 in the thickness direction DR3 of the substrate SUB, the second bank BN2, the first enhancing layer EHL1, the second enhancing layer EHL2, the organic encapsulation layer TFE2, and the wing portion TL3_W of the third inorganic layer TL3 may be sequentially disposed. The third opening OPE3 and the third emission area EA3 may not overlap with the first enhancing layer EHL1 and the second enhancing layer EHL2.

Each of the first enhancing layer EHL1 and the second enhancing layer EHL2 may maintain a constant or substantially constant thickness in the entire section. The first enhancing layer EHL1 may have the same or substantially the same thickness t1 on the second bank BN2, the body portion TL1_B of the first inorganic layer TL1, and the bottom surface, the first side surface, and the second side surface of the wing portion TL1_W. The second enhancing layer EHL2 may have the same or substantially the same thickness t2 on the first enhancing layer EHL1, the body portion TL2_B of the second inorganic layer TL2, and the bottom surface, the first side surface, and the second side surface of the wing portion TL2_W. The thickness of each of the first enhancing layer EHL1 and the second enhancing layer EHL2 may be controlled by adjusting a film forming process thereof. The thickness t1 of the first enhancing layer EHL1 and the thickness t2 of the second enhancing layer EHL2 may be equal to or substantially equal to each other, or may be different from each other. In an embodiment, the thickness t1 of the first enhancing layer EHL1 and the thickness t2 of the second enhancing layer EHL2 may be different from each other.

The thickness t1 of the first enhancing layer EHL1 and the thickness t2 of the second enhancing layer EHL2 may be equal to or larger than 0.5 Å. The first enhancing layer EHL1 and the second enhancing layer EHL2 may be formed to have a thin thickness by using an atomic layer deposition (ALD) method. The first enhancing layer EHL1 and the second enhancing layer EHL2 may be formed up to thicknesses t3 and t4 of the undercut structures of the first inorganic layer TL1 and the second inorganic layer TL2. The thickness t1 of the first enhancing layer EHL1 may be equal to or less than a distance t3 between the bottom surface of the wing portion TL1_W of the first inorganic layer TL1 and the top surface of the second bank BN2. The thickness t2 of the second enhancing layer EHL2 may be equal to or less than a distance t4 between the bottom surface of the wing portion TL2_W of the second inorganic layer TL2 and the top surface of the first enhancing layer EHL1.

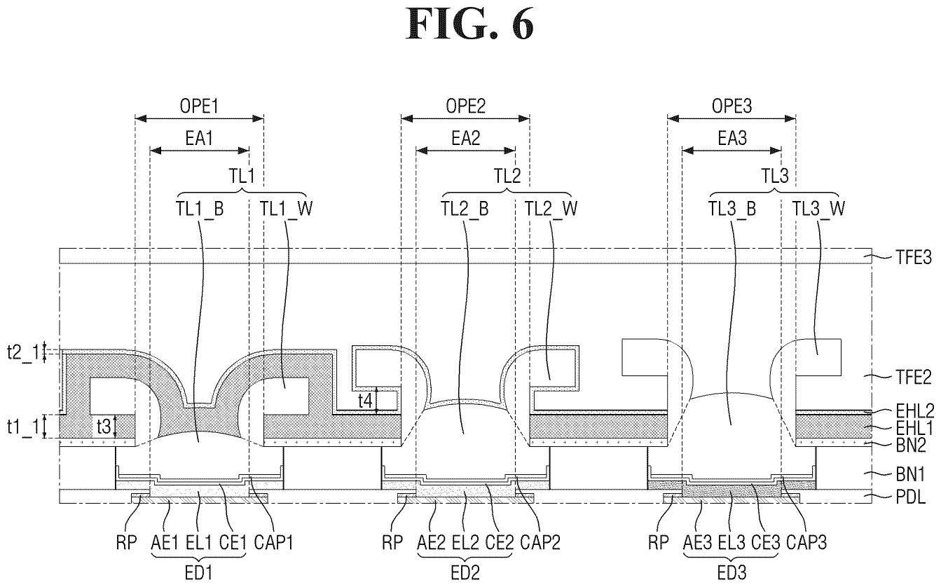

FIG. 6 is a cross-sectional view showing a light emitting element layer and a thin film encapsulation layer of a display device according to another embodiment. In FIG. 6, a thickness t1_1 of the first enhancing layer EHL1 is different from that of FIG. 5. As the first enhancing layer EHL1 of FIG. 5 has a thinner thickness, the first enhancing layer EHL1, the second enhancing layer EHL2, and the organic encapsulation layer TFE2 may be disposed in the undercut structure of the wing portion TL1_W1 of the first inorganic layer TL1. As the thickness t1_1 of the first enhancing layer EHL1 of FIG. 6 is equal to or substantially equal to the distance t3 between the bottom surface of the wing portion TL1_W of the first inorganic layer TL1 and the top surface of the second bank BN2, the undercut structure of the wing portion TL1_W1 of the first inorganic layer TL1 may be filled with the first enhancing layer EHL1. Although not shown in the drawings, the thickness t2 of the second enhancing layer EHL2 may also be equal to or close to the distance t4 between the bottom surface of the wing portion TL2_W of the second inorganic layer TL2 and the top surface of the first enhancing layer EHL1.

The material of the first enhancing layer EHL1 and the second enhancing layer EHL2 may not be particularly limited, as long as they can be formed by the ALD method. In an embodiment, each of the first enhancing layer EHL1 and the second enhancing layer EHL2 may include, but is not limited to, silicon oxide, aluminum oxide, zirconium oxide, hafnium oxide, cesium oxide, iron oxide, indium oxide, molybdenum oxide, or tin oxide. The first enhancing layer EHL1 and the second enhancing layer EHL2 may include the same material as each other, or may include different materials from each other. As an example, the first enhancing layer EHL1 and the second enhancing layer EHL2 may include silicon oxide or aluminum oxide.

The organic encapsulation layer TFE2 is disposed on the lower inorganic encapsulation layers TL1, TL2, and TL3, the first enhancing layer EHL1, and the second enhancing layer EHL2. A portion of the organic encapsulation layer TFE2 may be disposed between the top surface of the second enhancing layer EHL2 and the wing portion TL3_W of the third inorganic layer TL3. Depending on the thicknesses t1 and t2 of the first and second enhancing layers EHL1 and EHL2, a portion of the organic encapsulation layer TFE2 may or may not be disposed in the undercuts of the wing portions TL1_W and TL2_W of the first inorganic layer TL1 and the second inorganic layer TL2. The organic encapsulation layer TFE2 may not be in contact with the first inorganic layer TL1 and the second inorganic layer TL2, but may be in contact with the third inorganic layer TL3. The organic encapsulation layer TFE2 may not be in contact with the second bank BN2 in the display area DA.

The upper inorganic encapsulation layer TFE3 may be disposed on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

A light blocking layer may be selectively disposed on the thin film encapsulation layer TFEL. The light blocking layer may be positioned between the emission areas EA1, EA2, and EA3. The light blocking layer may include a light absorbing material. For example, the light blocking layer may include an inorganic black pigment or an organic black pigment. The inorganic black pigment may be carbon black, and the organic black pigment may include at least one of lactam black, perylene black, or aniline black, but the present disclosure is not limited thereto. The light blocking layer may prevent or substantially prevent visible light infiltration and color mixture between the first to third emission areas EA1, EA2, and EA3, which may lead to the improvement of color reproducibility of the display device 10.

The display device 10 may include the plurality of color filters CF1, CF2, and CF3 disposed on the emission areas EA1, EA2, and EA3 (e.g., see FIG. 4). Each of the plurality of color filters CF1, CF2, and CF3 may include a filtering pattern area and a light blocking area. The filtering pattern areas may be formed to overlap with the emission areas EA1, EA2, and EA3, or the openings of the bank structures BNS, and may form a light exit area from which light emitted from the emission areas EA1, EA2, and EA3 is emitted. The light blocking area is an area in which the plurality of color filters CF1, CF2, and CF3 are stacked so that light cannot be transmitted.

The color filters CF1, CF2, and CF3 may include a first color filter CF1, a second color filter CF2, and a third color filter CF3 disposed to correspond to the different emission areas EA1, EA2, and EA3, respectively. The color filters CF1, CF2, and CF3 may include a colorant, such as a dye or a pigment, that absorbs light in a wavelength band other than a specific wavelength band, and may be disposed to correspond to the color of the light emitted from the emission areas EA1, EA2, and EA3. For example, the first color filter CF1 may be a red color filter that is disposed to overlap with the first emission area EA1 and transmits only the first light of the red color. The second color filter CF2 may be a green color filter that is disposed to overlap with the second emission area EA2 and transmits only the second light of the green color. The third color filter CF3 may be a blue color filter that is disposed to overlap with the third emission area EA3 and transmits only the third light of the blue color.

In the display device 10, the color filters CF1, CF2, and CF3 are disposed to overlap with each other, so that the intensity of the reflected light by external light may be reduced. Furthermore, the color of the reflected light by the external light may be controlled by adjusting the disposition, shape, and area of the color filters CF1, CF2, and CF3 in a plan view.

An overcoat layer OC may be disposed on the color filters CF1, CF2, and CF3 to planarize or substantially planarize the top ends of the color filters CF1, CF2, and CF3. The overcoat layer OC may be a colorless light transmissive layer that does not have a color in a visible light band. For example, the overcoat layer OC may include a colorless light transmissive organic material, such as an acrylic resin.

Hereinafter, a fabrication process of the display device 10 according to an embodiment will be described in more detail with reference to the other drawings.

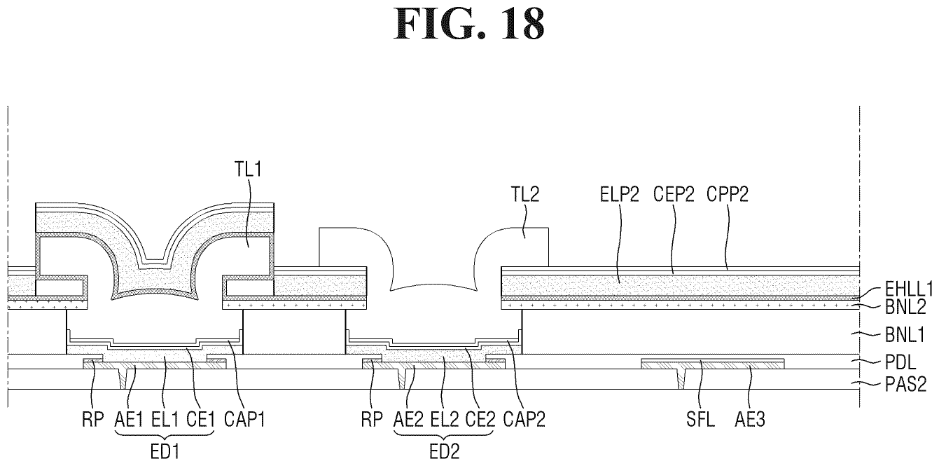

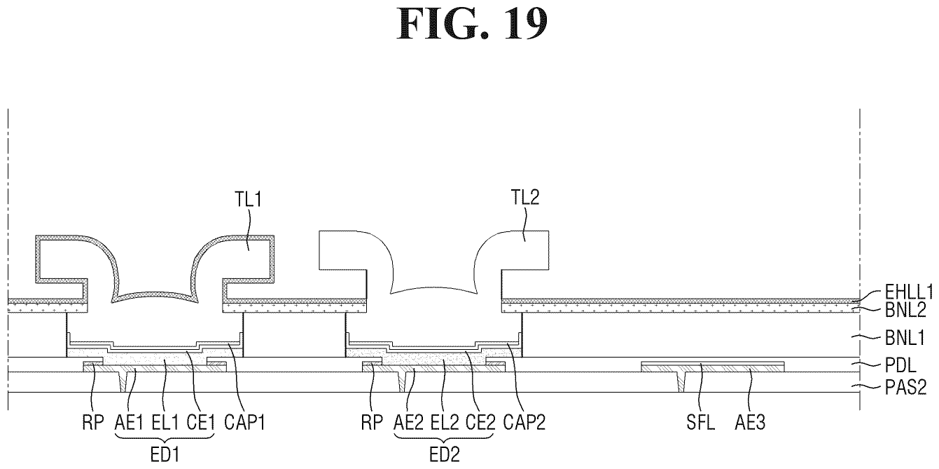

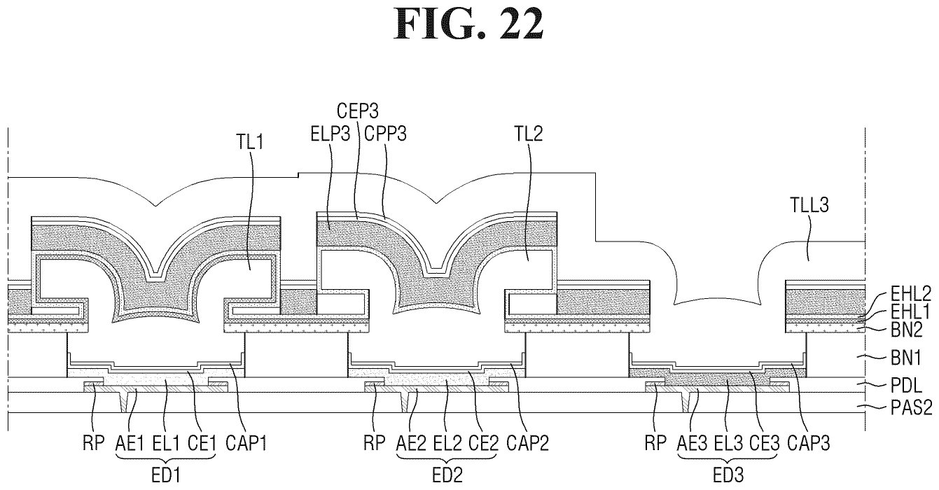

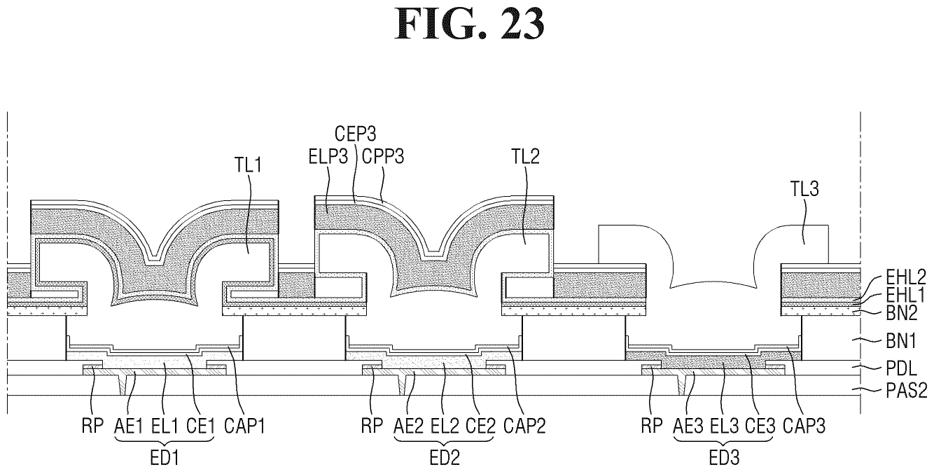

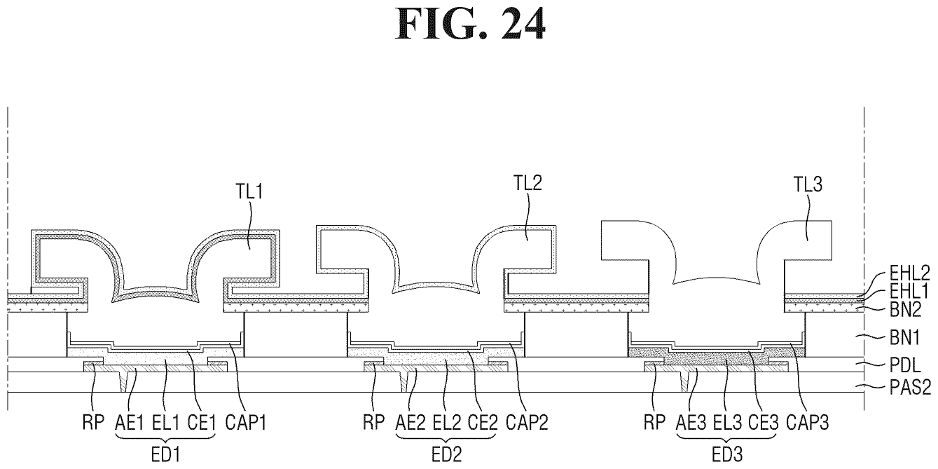

FIGS. 7 through 24 are cross-sectional views sequentially illustrating a fabrication process of a display device according to an embodiment. FIGS. 7 through 24 schematically illustrate a process of forming the light emitting elements ED and the bank structure BNS as the light emitting element layer EML of the display device 10, and the thin film encapsulation layer TFEL. Hereinafter, with respect to the fabrication process of the display device 10, a detailed description of the formation process of each layer will be omitted, and the formation order of each layer will be described in more detail.

Referring to FIG. 7, the plurality of pixel electrodes AE1, AE2, and AE3 that are spaced apart from each other, the sacrificial layer SFL, the pixel defining layer PDL, and a plurality of bank material layers BNL1 and BNL2 are formed on the entire or substantially entire second passivation layer PAS2.

Although not illustrated in the drawing, the thin film transistor layer TFTL may be disposed on the substrate SUB, and the structure of the thin film transistor layer TFTL is the same as described above with reference to FIG. 4. As such, redundant description thereof will not be repeated.

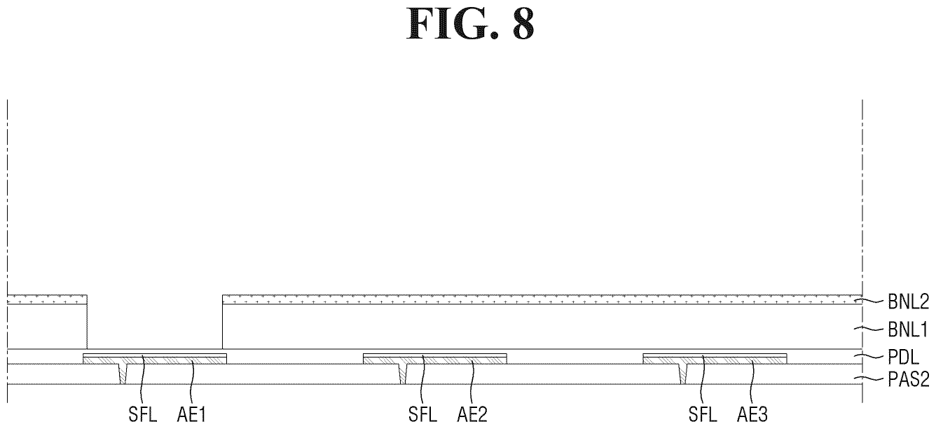

Next, referring to FIG. 8, a photoresist is formed on the second bank material layer BNL2, and a first etching process (1^{st} etching) for partially etching the first and second bank material layers BNL1 and BNL2 using the photoresist as a mask is performed. A hole may be formed through the first etching process. The photoresists may be disposed to be spaced apart from each other on the second bank material layer BNL2, and may be disposed to expose a region overlapping with the first pixel electrode AE1 from among the plurality of pixel electrodes AE1, AE2, and AE3.

In an embodiment, the first etching process (1^{st} etching) may be performed as anisotropic dry etching. The first opening OPE1 (e.g., see FIG. 4) of the second bank material layer BNL2 may be formed through the first etching process.

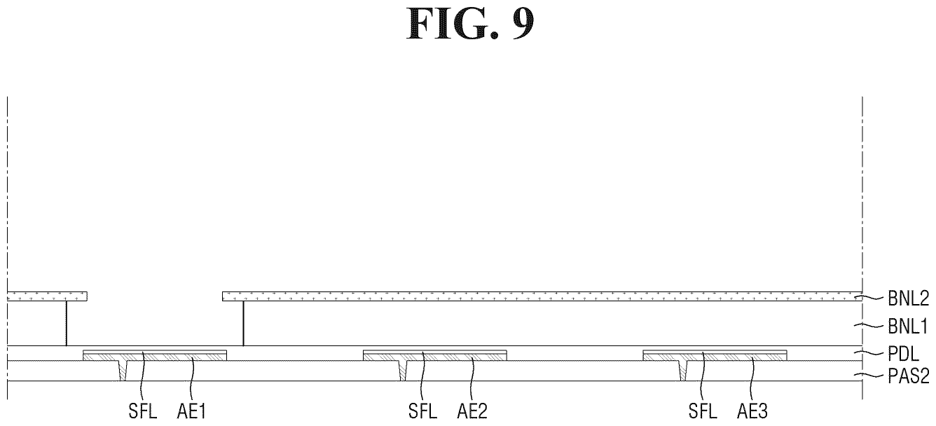

Next, referring to FIG. 9, the undercut structure of the first bank material layer BNL1 may be formed by a second etching process (2^{nd} etching). The etching rate of the first bank material layer BNL1 may be higher than that of the second bank material layer BNL2, and the side surface of the second bank material layer BNL2 may be formed to protrude more than the side surface of the first bank material layer BNL1. An undercut of the first bank material layer BNL1 may be formed under the second bank material layer BNL2. In an embodiment, the second etching process may be isotropic wet etching. The second etching process may use an alkali-based etchant.

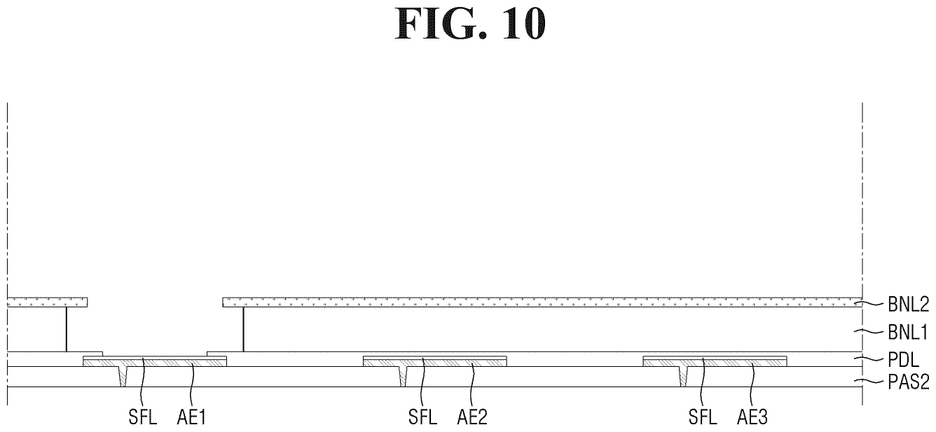

Subsequently, as shown in FIG. 10, a portion of the pixel defining layer PDL may be removed through a third etching process (3^{rd} etching) to expose the sacrificial layer SFL. In an embodiment, the third etching process may be a dry etching process.

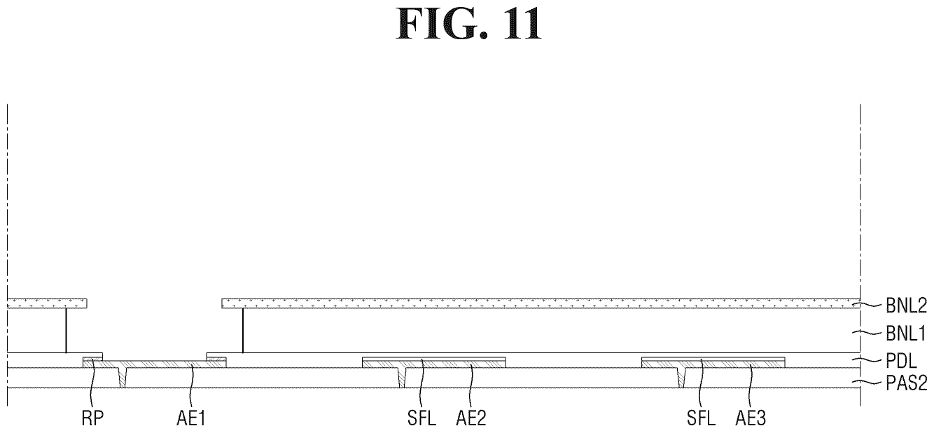

Next, referring to FIG. 11, a portion of the sacrificial layer SFL may be removed through a fourth etching process (4^{th} etching) to expose the first pixel electrode AE1. In an embodiment, the fourth etching process may be a wet etching process.

The sacrificial layer SFL may protect the pixel electrodes AE1, AE2, and AE3 from plasma in the dry etching process. The sacrificial layer SFL may not be completely removed in the fourth etching process, and may remain as a part of the residual pattern RP between the pixel defining layer PDL and the pixel electrodes AE1, AE2, and AE3.

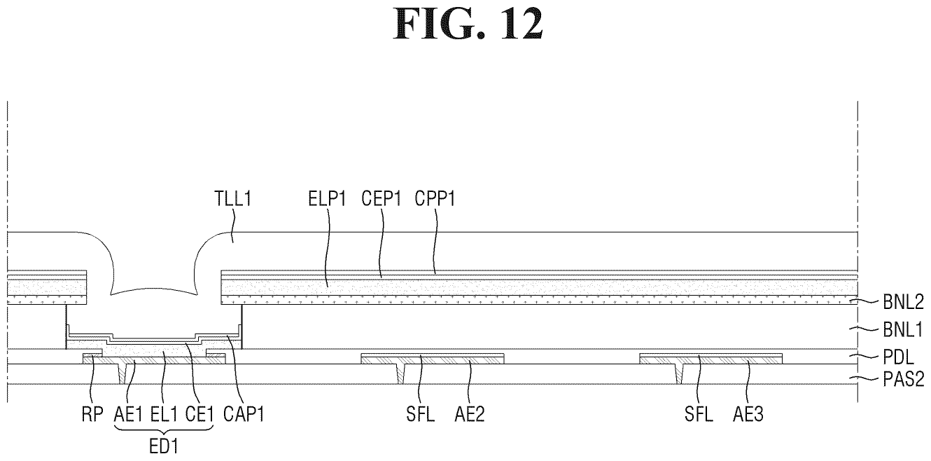

Subsequently, as shown in FIG. 12, the first light emitting layer EL1 and the first common electrode CE1 are sequentially stacked on the first pixel electrode AE1 to form the first light emitting element ED1, and the first capping layer CAP1 is formed on the first common electrode CE1. Here, because the first light emitting layer EL1, the first common electrode CE1, and the first capping layer CAP1 are formed on the entire or substantially entire surface of the substrate, a first emission pattern layer ELP1, a first electrode pattern layer CEP1, and a first capping pattern layer CPP1 may also be formed on the second bank material layer BNL2.

As the material deposited on the entire or substantially entire surface of the substrate SUB may be cut off (e.g., separated) by the protruding side surface and the tip of the second bank material layer BNL2, the first light emitting layer EL1 and the first emission pattern layer ELP1 may be separated from each other, the first common electrode CE1 and the first electrode pattern layer CEP1 may be separated from each other, and the first capping layer CAP1 and the first capping pattern layer CPP1 may be separated from each other. The first light emitting layer EL1 may be formed on the first pixel electrode AE1, and the first emission pattern layer ELP1 may be formed on the second bank material layer BNL2. At the same time as the first common electrode CE1 is formed on the first light emitting layer EL1, the first electrode pattern layer CEP1 may be formed on the first emission pattern layer ELP1.

The first light emitting layer EL1 and the first common electrode CE1 may be formed through a thermal deposition process. Within the opening, deposition of the materials may not be smoothly performed due to the tip of the second bank material layer BNL2. Because, however, the materials of the first light emitting layer EL1 and the first common electrode CE1 may be deposited in an inclined direction rather than in a direction perpendicular to or substantially perpendicular to the top surface of the substrate, they may be deposited even in the region hidden by the tip of the second bank material BNL2.

The deposition process of forming the common electrodes CE1, CE2, and CE3 may be performed at an angle inclined to be relatively closer to a horizontal direction compared to the deposition process of forming the light emitting layers EL1, EL2, and EL3. Accordingly, the common electrodes CE1, CE2, and CE3 may be in contact with the side surface of the first bank material layer BNL1 in larger areas compared to those of the light emitting layers EL1, EL2, and EL3. As another example, the common electrodes CE1, CE2, and CE3 may be deposited to higher positions on the side surface of the first bank material layer BNL1 compared to those of the light emitting layers EL1, EL2, and EL3. The different common electrodes CE1, CE2, and CE3 may be electrically connected to each other while being in contact with the first bank material layer BNL1 having a high conductivity.

Next, a first inorganic material layer TLL1 covering the first capping layer CAP1 and the first capping pattern layer CPP1 is formed. In an embodiment, the first inorganic material layer TLL1 may be formed through a chemical vapor deposition (CVD) method. The first inorganic material layer TLL1 may be formed along the stepped portions of the first light emitting element ED1 and the bank structure BNS.

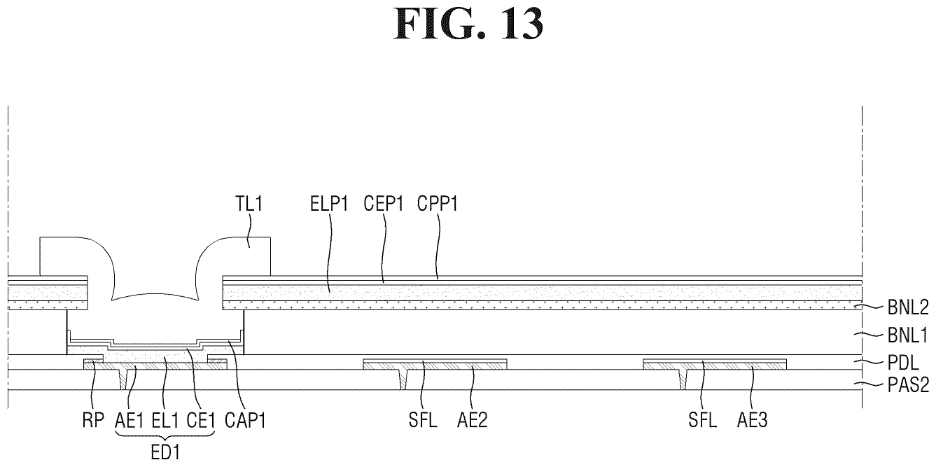

Next, referring to FIG. 13, a fifth etching process (5^{th} etching) is performed to remove a part of the first inorganic material layer TLL1 to thereby expose the first electrode pattern layer CEP1 (or the first capping pattern layer CPP1). A photoresist, which is a mask, is formed in a region overlapping with the first emission area EA1 and an edge area surrounding (e.g., around a periphery of) the first emission area EA1, and the first inorganic material layer TLL1 that is not covered with a mask is removed. Through the fifth etching process, the first inorganic layer TL1 remains in the region overlapping with the first emission area EA1 and the edge area surrounding it. In an embodiment, the fifth etching process may be anisotropic dry etching.

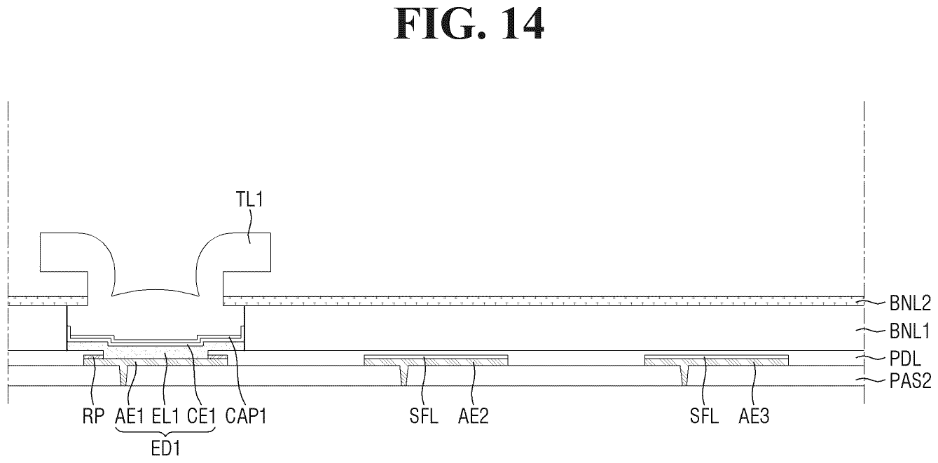

Subsequently, referring to FIG. 14, a sixth etching process (6^{th} etching) is performed to remove the first capping pattern layer CPP1, the first electrode pattern layer CEP1, and the first emission pattern layer ELP1 to thereby expose the second bank material layer BNL2. In an embodiment, the sixth etching process may include an isotropic wet etching process. The first emission pattern layer ELP1, the first electrode pattern layer CEP1, and the first capping pattern layer CPP1, which are disposed between the wing portion TL1_W of the first inorganic layer TL1 and the second bank material layer BNL2, may also be removed, so that the undercut structure of the first inorganic layer TL1 may be formed.

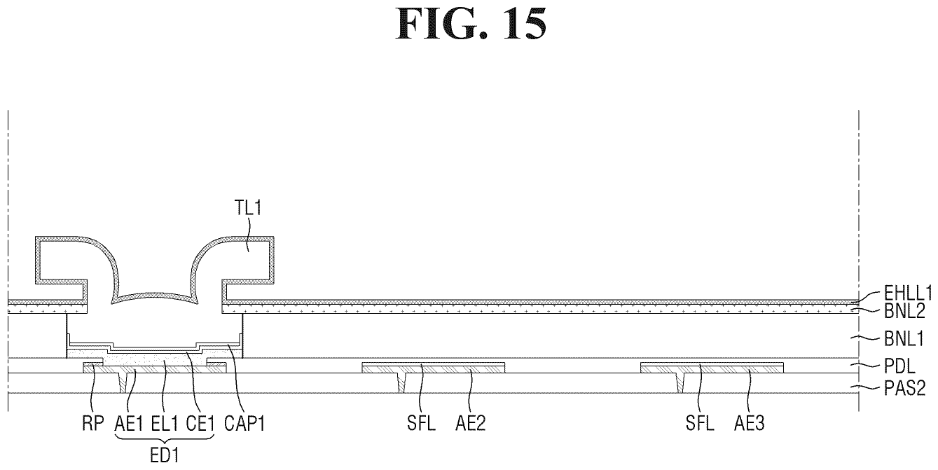

Next, as shown in FIG. 15, a first enhancing material layer EHLL1 is formed on the first inorganic layer TL1 and the second bank material layer BNL2. The first enhancing material layer EHLL1 may be formed by using an atomic layer deposition (ALD) method. As the ALD method has excellent step coverage, the first enhancing material layer EHLL1 may be formed inside the undercut of the first inorganic layer TL1 as well. The first enhancing material layer EHLL1 may cover all of the bottom surface, the first side surface, and the top surface of the wing portion TL1_W1 of the first inorganic layer TL1, and may have a thin thickness.

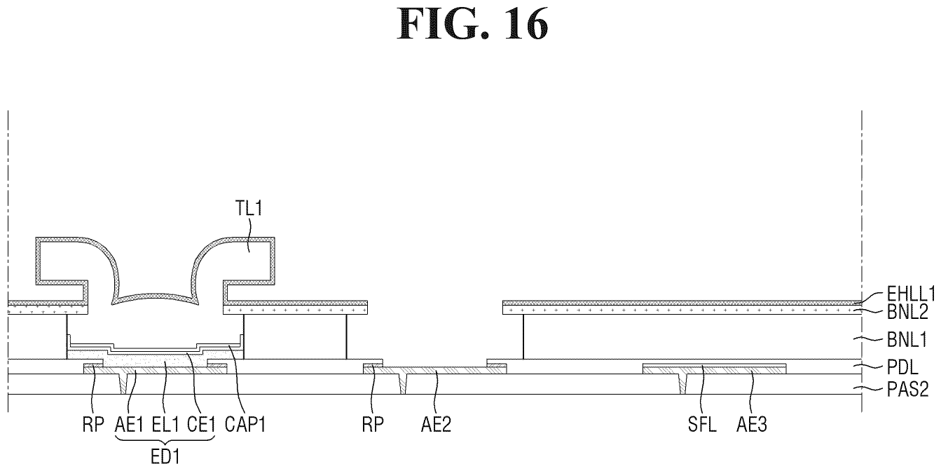

Subsequently, by repeating the processes shown in FIGS. 8 to 11, the second opening OPE2 of the bank structure BNS may be formed as shown in FIG. 16. Through this process, the second pixel electrode AE2 may be exposed.

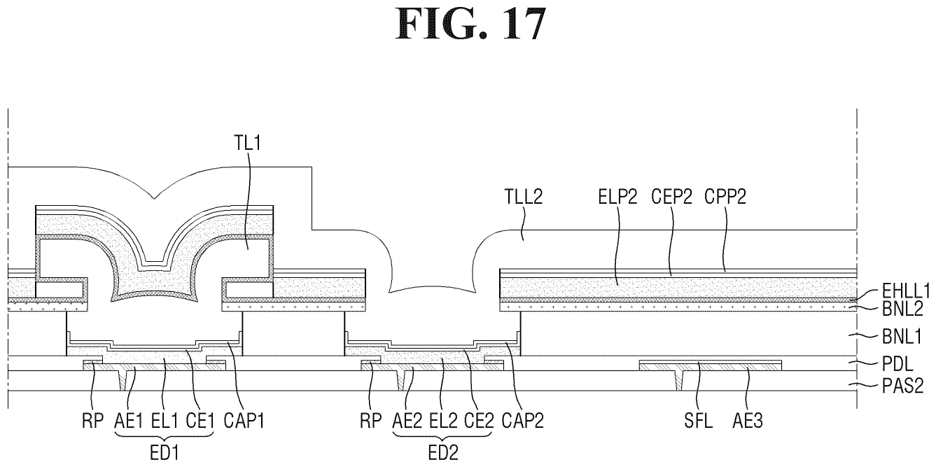

FIGS. 17 through 19 illustrate a process of forming the second light emitting element ED2 and the second inorganic layer TL2. This process may be similar to those of FIGS. 12 to 14. However, in an etching or cleaning process during this process, the first inorganic layer TL1 is protected by the first enhancing material layer EHLL1, so that moisture permeation and damage to the first light emitting element ED1 may be avoided. Through this process, the first enhancing material layer EHLL1 may be exposed.

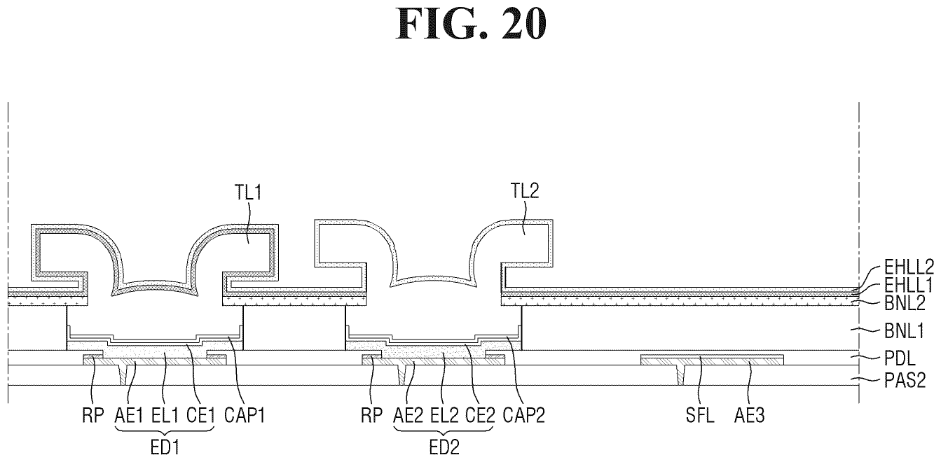

Referring to FIG. 20, a second enhancing material layer EHLL2 is formed on the second inorganic layer TL2 and the first enhancing material layer EHLL1. This process may be performed in a similar way to that of FIG. 15.

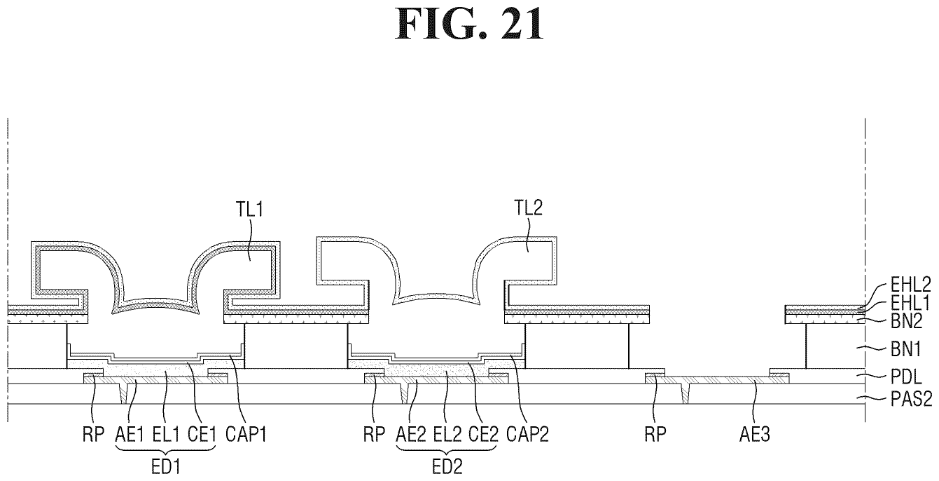

Next, referring to FIGS. 21 through 24, the third light emitting element ED3 and the third inorganic layer TL3 may be formed on the third pixel electrode AE3. This process may be performed in a similar way to that of FIGS. 8 to 14, so that the undercut structure of the third inorganic layer TL3 may be obtained.

Subsequently, the organic encapsulation layer TFE2 may be formed on the third inorganic layer TL3. A portion of the organic encapsulation layer TFE2 may be disposed inside the undercut between the wing portion TL3_W of the third inorganic layer TL3 and the second enhancing layer EHL2.

In addition, by forming the organic encapsulation layer TFE2 and the upper inorganic encapsulation layer TFE3 of the thin film encapsulation layer TFEL, the color filter layer CFL, and the overcoat layer OC on the light emitting elements ED1, ED2, and ED3, and the bank structure BNS, the display device 10 may be fabricated. The structures of the thin film encapsulation layer TFEL, the color filter layer CFL, and the overcoat layer OC are the same as those described above, and thus, redundant description thereof is not repeated.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a first pixel electrode on a substrate;
a pixel defining layer on the substrate, and exposing the first pixel electrode;
a first light emitting layer on the first pixel electrode;
a first common electrode on the first light emitting layer;
a first bank on the pixel defining layer;
a second bank on the first bank, and comprising a side surface protruding beyond a side surface of the first bank;
a first inorganic layer comprising:
a body portion on the first common electrode; and
a wing portion protruding from the body portion, and spaced from a top surface of the second bank;
a first enhancing layer between the wing portion of the first inorganic layer and the top surface of the second bank, and on the first inorganic layer; and
an organic encapsulation layer on the first enhancing layer.

2. The display device of claim 1, wherein the first enhancing layer comprises the same thickness on the second bank and the first inorganic layer.

3. The display device of claim 1, wherein a thickness of the first enhancing layer is equal to or larger than 0.5 Å, and is equal to or smaller than a distance between a bottom surface of the wing portion of the first inorganic layer and the top surface of the second bank.

4. The display device of claim 1, wherein the first enhancing layer comprises silicon oxide, aluminum oxide, zirconium oxide, hafnium oxide, cesium oxide, iron oxide, indium oxide, molybdenum oxide, or tin oxide.

5. The display device of claim 1, further comprising:
a second pixel electrode spaced from the first pixel electrode on the substrate;
a second light emitting layer on the second pixel electrode;
a second common electrode on the second light emitting layer, and spaced from the first common electrode;
a second inorganic layer comprising:
a body portion on the second common electrode; and
a wing portion protruding from the body portion of the second inorganic layer, and spaced from the top surface of the second bank; and
a second enhancing layer between the first enhancing layer and the organic encapsulation layer, and between the wing portion of the second inorganic layer and the top surface of the second bank.

6. The display device of claim 5, wherein a thickness of the first enhancing layer and a thickness of the second enhancing layer are different from each other.

7. The display device of claim 5, wherein the second bank comprises a first opening overlapping with the first common electrode, and a second opening overlapping with the second common electrode, and
wherein the first enhancing layer overlaps with the first opening of the second bank, and does not overlap with the second opening of the second bank.

8. The display device of claim 7, wherein the second enhancing layer overlaps with the first opening and the second opening of the second bank.

9. The display device of claim 5, wherein, in a region where the wing portion of the second inorganic layer and the second bank overlap with each other in a thickness direction of the substrate, the second bank, the first enhancing layer, the second enhancing layer, and the wing portion of the second inorganic layer are sequentially located on one another.

10. The display device of claim 5, wherein the first enhancing layer, the second enhancing layer, and the organic encapsulation layer are sequentially located on the body portion of the first inorganic layer.

11. The display device of claim 5, wherein the second enhancing layer is located on the body portion and the wing portion of the second inorganic layer.

12. The display device of claim 5, wherein the second inorganic layer is in contact with the second bank, the first enhancing layer, and the second enhancing layer.

13. The display device of claim 7, further comprising:
a third pixel electrode spaced from the first pixel electrode and the second pixel electrode on the substrate;
a third light emitting layer on the third pixel electrode;
a third common electrode on the third light emitting layer, and spaced from the first common electrode and the second common electrode; and
a third inorganic layer comprising:
a body portion on the third common electrode; and
a wing portion protruding from the body portion of the third inorganic layer, and spaced from the top surface of the second bank.

14. The display device of claim 13, wherein the second bank further comprises a third opening overlapping with the third common electrode, and
wherein the first enhancing layer and the second enhancing layer do not overlap with the third opening of the second bank.

15. The display device of claim 13, wherein a bottom surface of the wing portion of the first inorganic layer is in contact with the first enhancing layer,
wherein a bottom surface of the wing portion of the second inorganic layer is in contact with the second enhancing layer, and
wherein a bottom surface of the wing portion of the third inorganic layer is in contact with the organic encapsulation layer.

16. A method for fabrication of a display device, comprising:
forming a plurality of pixel electrodes spaced from each other on a substrate;
forming a pixel defining layer exposing the pixel electrodes;
forming a first bank on the pixel defining layer;
forming a second bank protruding beyond a side surface of the first bank;
forming a first light emitting layer on a first pixel electrode from among the pixel electrodes, and a first emission pattern layer on the second bank;
forming a first common electrode on the first light emitting layer, and a first electrode pattern layer on the first emission pattern layer;
forming a first inorganic material layer on the first common electrode;
etching a part of the first inorganic material layer;
etching the first emission pattern layer and the first electrode pattern layer to expose the second bank; and
forming a first enhancing material layer on the second bank and the first inorganic material layer by using an atomic layer deposition (ALD) method.

17. The method of claim 16, wherein the etching of the first emission pattern layer and the first electrode pattern layer to expose the second bank comprises removing the first emission pattern layer and the first electrode pattern layer between the second bank and the first inorganic material layer.

18. The method of claim 16, wherein the forming of the first light emitting layer on the first pixel electrode from among the pixel electrodes, and the first emission pattern layer on the second bank comprises depositing a material on the substrate that is cut off by a protruding side surface of the second bank, and separated into the first light emitting layer and the first emission pattern layer.

19. The method of claim 16, further comprising:
forming a second light emitting layer on a second pixel electrode from among the pixel electrodes, and a second emission pattern layer on the first enhancing material layer;
forming a second common electrode on the second light emitting layer, and a second electrode pattern layer on the second emission pattern layer;
forming a second inorganic material layer on the second common electrode;
etching a part of the second inorganic material layer;
etching the second emission pattern layer and the second electrode pattern layer to expose the first enhancing material layer; and
forming a second enhancing material layer on the first enhancing material layer and the second inorganic material layer.

20. The method of claim 19, further comprising:
forming a third light emitting layer on a third pixel electrode from among the pixel electrodes, and a third emission pattern layer on the second enhancing material layer;
forming a third common electrode on the third light emitting layer, and a third electrode pattern layer on the third emission pattern layer;
forming a third inorganic material layer on the third common electrode;
etching a part of the third inorganic material layer;
etching the third emission pattern layer and the third electrode pattern layer to expose the second enhancing material layer; and
forming an organic encapsulation layer on the second enhancing material layer and the third inorganic material layer.
